(19) United States
(12) Patent Application Publication
(10) Pub. No.: US 2025/0020996 A1
(43) Pub. Date: Jan. 16, 2025

(54) ORGANOTIN PHOTORESISTS AND METHOD OF DEVELOPING PHOTOLITHOGRAPHY PATTERN

(71) Applicant: Feng Lu, Irvine, CA (US)

(72) Inventor: Feng Lu, Irvine, CA (US)

(21) Appl. No.: 18/513,536

(22) Filed: Nov. 18, 2023

Related U.S. Application Data
(60) Provisional application No. 63/525,450, filed on Jul. 7, 2023.

(51) Int. Cl. G03F 7/004; C07F 7/22; G03F 7/16

(52) U.S. Cl. CPC G03F 7/0042; C07F 7/2224; G03F 7/167; G03F 7/38

(57) ABSTRACT

The present invention relates to organotin photoresists and method of developing photolithography pattern; wherein organotin photoresists comprise (stannocenyl)tin compounds. Stannocenyl is bis(cyclopentadienyl)tin, or substituted bis(cyclopentadienyl)tin, wherein cyclopentadienyl comprises cyclopentadienyl C₅H₅ group, or substituted cyclopentadienyl C₅H₃R, C₅H₂R₂, C₅HR₃, C₅R₄, or C₅R₅ group. Method of developing photolithography pattern comprises sublimation or vaporization.

### RELATED U.S. APPLICATION DATA

Provisional application No 63/252,450, filed on Jul. 7, 2023.

### REFERENCES CITED

### U.S. Patent Documents

U.S. Pat. No. 10,228,618 B2 December 2019 Meyers et al.
U.S. Pat. No. 10,642,153 B2 May 2020 Meyers et al.
U.S. Pat. No. 10,732,505 B1 August 2020 Meyers et al.
U.S. Pat. No. 10,975,109 B2 April 2021 Edson et al.
U.S. Pat. No. 11,092,889 B2 August 2021 Moon et al.
2023/0312618 A1 October 2023 Lu
2023/0312619 A1 October 2023 Lu OTHER PUBLICATIONS
Anderson et al., “The SEMATECH Berkeley MET: extending EUV learning down to 16 nm half pitch”, Proc. Of SPIE, vol. 7969, 2011, 7 pp.
Baker et al., “The photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948.
Baxter et al., “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069.
Bellabarba et al., “Synthesis of metallocene of zirconium, hafnium, manganese, iron, tin, lead and half-sandwich complexes of rhodium and iridium containing the ligands (η-C₅R₄CR′₂PMe₂), where R and R′ may be H or Me″, Journal of Organometallic Chemistry, 640 (2001) 93-112.
Bos et al., “Oxidative addition reactions of some organotin(II) and organic tin(II) compounds”, Journal of Organometallic Chemistry, 67(1974) C13-C15.
Bos et al., “Oxidative addition reactions of dicyclopentadienyltin(II) and of tin(II) bis(acetylacetonate) with organic halides. The preparation of compounds of the type RSn(acac)₂X”, Journal of Organometallic Chemistry, 99 (1975) 397-405.
Chandrasekhar et al., “Organotin assemblies containing Sn—O bonds”, Coordination Chemistry Reviews 2002, 235, 1-52.
Elschenbroich, et al., “Tetrakis([5]trovacenyl)tin: synthesis, structure, and intramolecular communication”, Organometallics 2007, 26, 4025-4030.
Elschenbroich, et al., “Synthesis, electrochemical behavior and EPR study of organometallic [5]trovacenylthiol (η⁷—C₇H₇)V(η⁵—C₅H₄SH) and structural characterization of ansa-trithio[3]trovacenophane”, Journal of Organometallic Chemistry 755 (2014) 58-63.
Elschenbroich, et al., “Bis([5]trovacenyl)dichalcogenides: Synthesis, Structure, and Study of Intramolecular Communication”, Zeitschrift für Anorganische und Allgemeine Chemie, 2011, 637, 1750-1755.
Elschenbroich, et al., “α,ω-Di([5]trovacenyl) Sulfides TVC-Sn-TVC (n=1-4) and TVC-SCH₂S-TVC: a Study in Intramolecular Communication”, European Journal of Inorganic Chemistry, 2012, 3929-3936.
Elschenbroich, et al., “[5]Trovacenol, (η⁷—C₇H₇)V(η⁵—C₅H₄OH): Synthesis and Structural Characterization”, Organometallics, 2002, 21 5152-5154.
Elschenbroich, et al., “Exchange Interaction Mediated by O—H—O Hydrogen Bonds: Synthesis, Structure, and EPR Study of the Paramagnetic Organometallic Carboxylic Acid (η⁷—C₇H₇)V(η⁵—C₅H₄COOH)”, Journal of the American Chemical Society, 1997, 119, 7452-7457.
Hanssgen et al., “Synthese der ersten mon-t-butylzinnelementverbindungen”, Journal of Organometallic Chemistry 293 (1985) 191-195.
Harrison et al., “Tin-199m Mössbauer and nuclear magnetic resonance study of dicyclopentadienyltin(II)”, Journal of the American of Chemical Society, 19, 1969, 6885-6886.
Herzog et al., “Eine rationelle anaerobe Arbeitsmethod”, Zeitschrift fUr Chemie, 4 (1964) 1.
Janiak, “Stannocene as cyclopentadienyl transfer agent in transmetallation reactions with lanthanide metals for the synthesis of tris(cyclopentadienyl)lanthanides”, Zeitschrift fUr Anorganische und Allgemeine Chemie, 2010, 636 (13-14), 2387-2391.
Jones et al., “Amino-derivatives of metals and metalloids. Part I. Preparation of aminostannenes, stannylamines and stannazanes”, Journal of the Chemical Society, 1944-1951 (1965).
Jutzi et al., “Synthese und Reaktionen von Pentamethylcyclopentadienylzinn-Verbindungen”, Journal of Organometallic Chemistry, 164 (1979) 141-152.
Jutzi et al., “Preparation of tin and germanium metallocenes from tetravalent precursors”, Organometallics 1986, 5, 1201-1204.
Leskelä et al., “ALD precursors chemistry: evolution and future challenges”, Journal Physics IV., 9, 837-849 (1999).
Leskelä et al., “Atomic layer deposition (ALD): from precursors to thin film structures”, Thin Solid Film 409, 138-146 (2002).
Lu, et al., “Electrochemistry of dinuclear organometallic [5]trovacenyl derivatives bridged by group 14 elements (Si, Ge, Sn, Pb)”, European Journal of Inorganic Chemistry, 2017, 82-87.
Lu, “Elemental sulfur as soft oxidant for facile one-pot preparation of air-sensitive organometallic di[5]trovacenyldichalcogenides”, Inorganic Chemistry Communication, 37 (2013) 148-150.
Mack, “Fundamental principles of optical lithography”, John Wiley & Sons, Chichester, U.K. 2007.
Puff et al., “Zur Hydrolyse von Monoorganylzinn-trihalogeniden”, Journal of Organometallic Chemistry, 368, 173-183 (1989).
Stowers et al., “High resolution, high sensitivity inorganic resists”, Microelectronic Engineering, 86, 730-733 (2009).
Stowers et al., “Directly patterned inorganic hardmask for EUV lithography”, Proc. SPEIE 7969, 796915, (2011), http://dx.doi.org/10.1117/12.879542.
Wilkinson, in “Organic synthesis”, Wiley, Coll. Vol. 4, (1973) 473.
International Standard ISO 21348 “Space environment (natural and artificial)—process for determining solar irradiances”, First Edition 2007, Reference No. ISO 21348:2007, (20 pages).

### CROSS REFERENCE TO RELATED APPLICATIONS

This application claims priority to U.S. provisional patent application No. 63/525,450 filed on Jul. 7, 2023 to Lu, entitled “Organotin photoresists and method of developing photolithography pattern”, of which is entirely incorporated herein by reference.

### FIELD OF INVENTION

The present invention relates to organotin photoresists for actinic radiation and method of developing photolithography pattern; wherein organotin photoresists comprise (stannocenyl)tin compounds.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in the exposed region, which would result in different properties between the exposed and unexposed regions. The properties of EUV photoresist, such as resolution, sensitivity, line edge roughness (LER), line width roughness (LWR), etch resistance and ability to form thinner layer are important in photolithography.

Organometallic compounds have high ultraviolet light adsorption because metals have high adsorption capacity of ultraviolet radiation with various carbon-metal (C-M) bond dissociation energy (BDE), and then can be used as photoresists and/or the precursors for photolithography at smaller level (e.g., <7 nm), which is of great interests for radiation lithography. Among those promising advanced materials, particularly organometallic tin compounds can provide photoresist patterning with significant advantages, such as improved resolution, sensitivity, etch resistance, and lower line width/edge roughness without pattern collapse because of strong EUV radiation adsorption of tin, which have been demonstrated.

The general method for developing photolithography pattering includes wet liquid solvents development method, or dry gaseous development method. Wet liquid solvents development methods utilized liquid organic solvents or aqueous solvents to remove exposed portions or unexposed portions of photoresists, which corresponding to positive or negative patterning. Organometallic compounds, particularly metallocene-based compounds, can be sublimized or vaporized under high vacuum and temperature. Therefore, organometallic compound photoresist can be deposited on the surface of semiconductor substrate by chemical vapor deposition (CVD), physical vapor deposition (PVD), atomic layer deposition (ALD), spin-on coating, or other approaches. After exposure to ultraviolet light (e.g., EUV 13.5 nm), exposed or irradiated portions of organometallic photoresists become non-sublimized or non-volatile or insoluble metallic complexes or polymetallic network complexes such as metal oxides, or metal oxide/hydroxide network complexes. While unexposed portion can be selectively removed by sublimation or vaporization for pattern development under ambient vacuum and temperature. The sublimation or vaporization development method avoids the usage of liquid organic solvents or aqueous solutions from wet development, and dry development method with gases like hydrogen halides, with environmentally friendly development and lower manufacturing cost. The sublimation or vaporization development method may avoid pattern collapses and defects due to rinse process. In addition, the followed post development rinse process may be omitted therefore.

### SUMMARY

In a first aspect, the present invention pertains to organotin photoresists and method of developing photolithography patterning. The present invention is to provide (stannocenyl)tin compound photoresists for photolithography patterning. The present invention is further to provide sublimation or vaporization method for patterning development under high vacuum and ambient temperature without pattern collapses and defects during microelectronic patterning, particularly for EUV lithography <7 nm.

In another aspect, the present invention pertains to a method of developing a photolithography pattern by sublimation or vaporization, comprising:
forming an organotin photoresist solution composition; wherein the forming the organotin photoresist solution composition comprises (stannocenyl)tin compound, a solvent, and/or an additive; wherein stannocenyl is bis(cyclopentadienyl)tin, or substituted bis(cyclopentadienyl)tin, wherein cyclopentadienyl comprises cyclopentadienyl C₅H₅ group, or substituted cyclopentadienyl C₅H₃R, C₅H₂R₂, C₅HR₃, C₅R₄, or C₅R₅ group; depositing organotin photoresist solution composition on a surface of the substrate; exposing organotin photoresists layer to actinic radiation to form a latent pattern; and developing the latent pattern by applying sublimation or vaporization method to remove unexposed organotin photoresist to form a photolithography pattern.

In a further aspect, the invention pertains to organometallic photoresists, which are radiation sensitive and become to un-sublimized or un-vaporized metallic complexes or polymetallic network complexes, such as metal oxides, after exposure to ultraviolet light, such as EUV or DUV. Meanwhile unexposed organometallic photoresists can be sublimized or vaporized under ambient vacuum and temperature, such as high vacuum and temperature without decomposition to form metallic complexes. The invention pertains to radiation sensitive organometallic photoresists, including but not limited to, organometallic tin (Sn), indium (In), antimony (Sb), bismuth (Bi), manganese (Mn), vanadium (V), titanium (Ti), chromium (Cr), selenium (Se), tellurium (Te), zirconium (Zr), hafnium (Hf), gallium (Ga), germanium (Ge) compounds, or a combination thereof.

In other aspects, the invention pertains to radiation sensitive organotin compound photoresists, which are suitable for photolithography patterning, such as EUV or DUV, or as the precursors, for example, for synthesizing organotin photoresist, or reacting with reactive gaseous atmosphere. In the present invention, organotin compound photoresists include, but not limited to, (stannocenyl)tin compounds. In some embodiments, organotin photoresists can be sublimized or vaporized under pressure ranging from 0.0001 torr to 100 torr, and temperature ranging from 20 to 300° C.

In another aspect, the invention pertains to radiation sensitive (stannocenyl)tin compound photoresists, wherein stannocenyl comprises bis(cyclopentadienyl)tin represented as below, and substituted bis(cyclopentadienyl)tin;

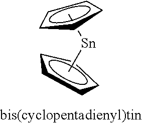

wherein cyclopentadienyl comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴, or η⁵ of isomers, wherein R is H, a linear or branched alkyl, alkenyl, alkynyl, or cycloalkyl group with 1 to 20 carbon atoms, or an aryl group with 6-20 carbon atoms, or an amino, cyano, ether, ester, halide, nitro, silyl, thiol, or carbonyl group.

In an additional aspect, the invention pertains to synthesize of radiation sensitive (stannocenyl)tin compounds, in which bis(cyclopentadienyl)tin ((η⁵—C₅H₅)₂Sn, stannocene, or Sc) is used as parent molecule for carrying out lithiation at one or two C₅ rings, such as mono-lithiation, or bi-lithiation, by strong bases, for example, methyllithium (MeLi), n-butyllithium (n-BuLi), s-butyllithium (s-BuLi), or t-butyllithium (t-BuLi), and then followed by further procedures to synthesize desired derivatives or compounds. Meanwhile, the as-synthesized (stannocenyl)tin compounds may further be used as the precursors to form organotin photoresists, for example, organotin clusters, with appropriate molecules such as water, oxygen.

In the present invention disclosure, (stannocenyl)tin compound or precursor is one or more selected from the following:

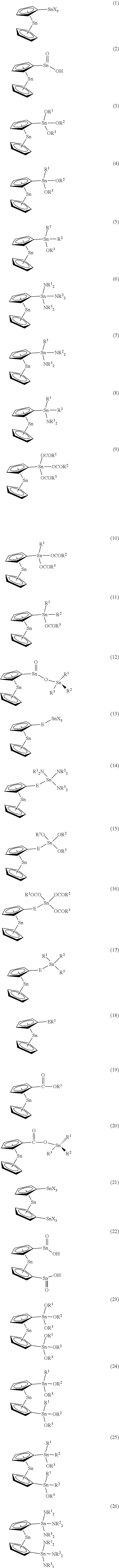

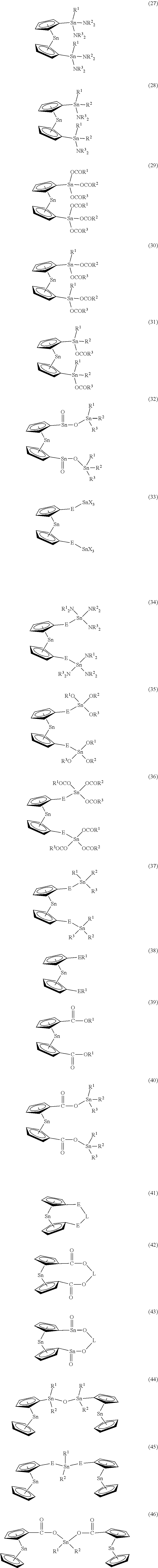

wherein R¹, R², R³, are each independently H, a substituted or unsubstituted alkyl, alkenyl, alkynyl, cycloalkyl, or cycloalkenyl group with 1 to 20 carbon atoms, or substituted or unsubstituted aryl group with 6-20 carbon atoms;
E=O, S, Se, or Te; X=F, Cl, Br, or I;
L is a linear or branched alkyl, alkenyl, alkylene, alkynyl, or cycloalkyl group with 1 to 20 carbon atoms, or a substituted or unsubstituted aryl group with 6-20 carbon atoms, or an amino, cyano, ether, ester, halide, nitro, silyl, thiol, or carbonyl group.

Furthermore, the invention pertains to the method of developing photolithography pattern comprising sublimation or vaporization, which offer the advantages for smaller features of photolithography patterning at <7 nm, particularly 1-3 nm, compared with conventional wet liquid solvents development methods, or dry gaseous development methods. The wetting and surface tension on the semiconductor substrate surface make the conventional development methods rather difficult at smaller pattering <7 nm, particularly 1-3 nm, along with pattern collapses and defects due to the liquid flows or gaseous flows and rinse process. Additionally, the conventional wet or dry development methods may not remove all the unexposed portions of organometallic photoresists due to the smaller pitch and space between two adjacent pitches at pretty small scale or <100% etch yield.

In a further aspect, the invention pertains to the methods for organometallic photoresists deposition on a surface of semiconductor substrate by wet deposition like spin-on coating, or dry deposition like chemical vapor deposition, physical vapor deposition, atomic layer deposition, or other approaches. In some embodiments, (stannocenyl)tin compound may be sublimized or vaporized for deposition over a substrate to form a layer. The sublimation deposition method may not need the general baking process from wet deposition method.

The invention relates to radiation sensitive organotin photoresists, which can be efficiently patterned in the presence of ultraviolet light, extreme ultraviolet light, deep ultraviolet light, or electron beam to form high resolution patterns with low line width roughness at <7 nm, and with high resolution, low dose and large contrast for <7 nm.

### BRIEF DESCRIPTION OF THE DRAWINGS

FIG. 1 is a flowchart of photolithography patterning processing including organotin photoresists deposition, pre-exposure bake, exposure, sublimation/vaporization development.

### DETAILED DESCRIPTION

The present invention relates to organotin photoresists and method of developing photolithography pattern; wherein organotin photoresists comprise (stannocenyl)tin compounds. Stannocenyl is bis(cyclopentadienyl)tin, or substituted bis(cyclopentadienyl)tin, wherein cyclopentadienyl comprises cyclopentadienyl C₅H₅ group, or substituted cyclopentadienyl C₅H₃R, C₅H₂R₂, C₅HR₃, C₅R₄, or C₅R₅ group. The method of developing photolithography pattern comprises sublimation or vaporization.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, or “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The terms “alkyl” or “alkyl group” refers to a saturated linear or branched-chain hydrocarbon of 1 to 20 carbon atoms. The terms “alkenyl, alkynyl, cycloalkyl” refers to hydrocarbon of 1 to 20 carbon atoms. The term “aryl” refers to unsubstituted or substituted aromatic group with 6-20 carbon atoms. The term “alkylene” refers to a saturated divalent hydrocarbons by removal of two hydrogen atoms from a saturated hydrocarbons of 1 to 20 carbon atoms, for example, methylene (—CH₂—), ethylene (—CH₂CH₂—), propylene (—CH₂CH₂CH₂—), or the like.

The term “halide” refers to the F, Cl, Br, or I. The term “nitro” refers to the —NO₂. The term “silyl” refers to the —SiR₂—, or —SiR₃ group. The term “thiol” refers to —SH group. The term “carbonyl” refers to the —C═O group. The term “oxo” refers to —O—, or =O. The term “amino” refers to the —NH₂, —NHR, or NR₂ group.

In the present disclosure, the term “substituted” refers to replacement of a hydrogen atom with a C1 to C20 alkyl group, a C1 to C20 alkene group, a C1 to C20 alkyne group, a C1 to C20 cycloalkyl group, a C6 to C20 aryl group, or other relevant groups.

EUV lithography is under the development for the mass production of next generation <7 nm node. EUV photoresists are required to achieve higher performance, higher sensitivity and resolution, and cost reduction.

EUV light has been applied for photolithography at about 13.5 nm. The EUV light can be generated from Sn plasma or Xe plasma source excited using high energy lasers or discharge pulses.

For conventional organic polymer photoresists, if the aspect ratio, which is the height divided by width, is too large that would lead to pattern structures susceptible to collapse, and also associated with surface tension, which would limit the application for smaller features like <7 nm.

For small feature sizes like <7 nm, such as 1-3 nm, the conventional chemically amplified (CA) organic polymer photoresists encounter critical issues, such as poor EUV light adsorption, low resolution, high line edge roughness (LER), increased pattern collapses and defects. In order to overcome the disadvantages from organic polymer photoresists, organometallic photoresists and relevant organometallic photosensitive compositions, particularly for EUV, have been called for.

Organometallic photoresists are used in EUV lithography because metals have high adsorption capacity of EUV radiation. Radiation sensitivity and thermal-, oxygen- and moisture-stability are important for organometallic photoresists. In some embodiments, organometallic photoresists may adsorb moisture and oxygen, which may result in decreasing stability, as well decreasing solubility in developer solutions. In addition, in some embodiments, photoresist layer may outgas volatile components prior to the radiation exposure and development operations, which may negatively affect the photolithography performance, pattern collapse and increase defects.

Organometallic tin photoresist layer is patterned by exposure to actinic radiation. Typically, the chemical properties of the photoresist regions struck by incident radiation change in a manner that depends on the type of photoresist used. Photoresist can be positive resist or negative resist. In some embodiments, positive resist refer to a photoresist material that when exposed to radiation (e.g., EUV) becomes soluble in a developer, while the region of the photoresist that is non-exposed (or exposed less) is insoluble in the developer. In some embodiments, on the contrary, negative resist refers to a photoresist material that when exposed to radiation becomes insoluble in the developer, while the region of the photoresist that is non-exposed (or exposed less) is soluble in the developer.

The physical and chemical properties of organometallic compounds which are suitable for photoresists determine the relevant properties for photolithography, particularly for EUV and DUV, wherein bond dissociated energy (BDE) of M-C(metal-carbon bond) plays the key role. M is metal, including but not limited to, tin (Sn), indium (In), antimony (Sb), bismuth (Bi), manganese (Mn), vanadium (V), titanium (Ti), chromium (Cr), selenium (Se), tellurium (Te), zirconium (Zr), hafnium (Hf), gallium (Ga), or germanium (Ge). Particularly, organotin photoresists are suitable for EUV or DUV photolithography patterning.

In general, metal central plays the key role in determining the absorption of photo radiation of organometallic photoresists. However, for organometallic compounds, the metal-bonded organic ligands (M-R, M=metal, R=organic ligands) may also influence the relevant absorption through M-C bonding. Tin atom provides strong absorption of extreme ultraviolet (EUV) light at 13.5 nm, therein tin cations can be selected based on the desired radiation and absorption cross section. Meanwhile the organic ligand bonded to tin also has absorption of EUV light. Therefore, the tuning and modification of organic ligands can change sensitivity, radiation absorption, or the desired control of material properties.

The bond dissociation energy (BDE) of Sn—C bond determines the light adsorption wavelength and corresponding smaller features and patterned structures.

Organotin photoresists have excellent (e.g., suitable) sensitivity to high energy light (e.g., EUV, DUV, X-ray, or laser) due to tin strong absorption of extreme ultraviolet (EUV) at about 13.5 nm. Accordingly, organotin photoresists have improved sensitivity, resolution, stability compared with conventional organic polymer or inorganic photoresists.

In some embodiments, organometallic (stannocenyl)tin compound photoresists include, but not limited to, oxide hydroxides (stannonic acid), anhydrides, hydroxides, alkoxides, amides, halides, carboxylic acids, chalcogenides, distannoxane (oxo), oxides, or esters.

In some embodiments, organometallic (stannocenyl)tin compound photoresists include stannocenyl-based derivatives, represented by the Chemical Formulas (1)-(46), but not limited to.

In some embodiments, organometallic (stannocenyl)tin compound photoresists are suitable for EUV or DUV photolithography patterning, and for sublimation or vaporization development processing under ambient vacuum and temperature, such as high vacuum and temperature.

Stannocenyl is bis(cyclopentadienyl)tin, or substituted bis(cyclopentadienyl)tin, wherein cyclopentadienyl comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴, or η⁵ of isomers, wherein R is H, an alkyl, alkenyl, alkynyl, or cycloalkyl group with 1 to 20 carbon atoms, or an aryl group with 6-20 carbon atoms, or an amino, cyano, ether, ester, halide, nitro, silyl, thiol, or carbonyl group. For example, R is H, methyl, ethyl, isopropyl, n-butyl, tert-butyl, tert-amyl, sec-butyl, pentyl, hexyl, neopentyl, cyclohexyl, cyclopentyl, cyclobutyl, cyclopropyl, phenyl, or a combination thereof.

Organometallic (stannocenyl)tin compound photoresists contain π bond, C—Sn bond and related interaction, and may have excellent (e.g., suitable) sensitivity to EUV radiation light due to tin adsorption high energy EUV ray at 13.5 nm. Accordingly, the related solution compositions may have improved sensitivity and stability compared with organic polymer or inorganic photoresists.

Cyclopentadienyl group (C₅H₅, or Cp) may impart photosensitivity to the compounds, and the Cp-Sn bond formed may promote suitable solubility in an organic solvent to the organometallic sandwich or half-sandwich tin compounds. Accordingly, these Cp-Sn bond containing organometallic sandwich or half-sandwich tin compounds according to an embodiment may have improved sensitivity, resolution and stability, and may suitable for EUV photoresists, and/or the precursors for EUV lithography to form tin oxide or tin oxide hydroxide film.

Organometallic (stannocenyl)tin compounds contain cyclopentadienyl-Sn bond (Cp-Sn bond). Cp-Sn bond is sensitive to UV light and occurs the radiation disruption to generate free radical when exposures to UV light, which has been demonstrated, for example, P. J. Baker, A. G. Davies, M.-W. Tse, “The photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅· radical. This study demonstrated cyclopentadienyl (C₅H₅) group or substituted cyclopentadienyl (e.g., C₅R₅) group is much more sensitive to UV light compared to alkyl (e.g., methyl, butyl) groups under identical conditions. This property will be beneficial to decrease EUV light dose and increase resolution.

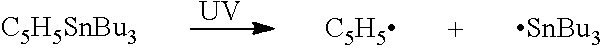

Organometallic (stannocenyl)tin compound photoresists have excellent sensitivity to EUV radiation light due to the tin adsorption high energy EUV ray at 13.5 nm (low expose dose photoresist, e.g., <20 mJ/cm²), and the disruption of Cp-Sn bond to form free radical, tin oxide and relative products, and toughness; low or free pattern defectivity at nanoscale. Accordingly, the solution composition of organometallic (stannocenyl)tin compound photoresist may have tight pitch (e.g., <10 nm), and may sustain the yield and deliver high resolution.

In the present disclosure, (stannocenyl)tin compound photoresist is one or more selected from the following:

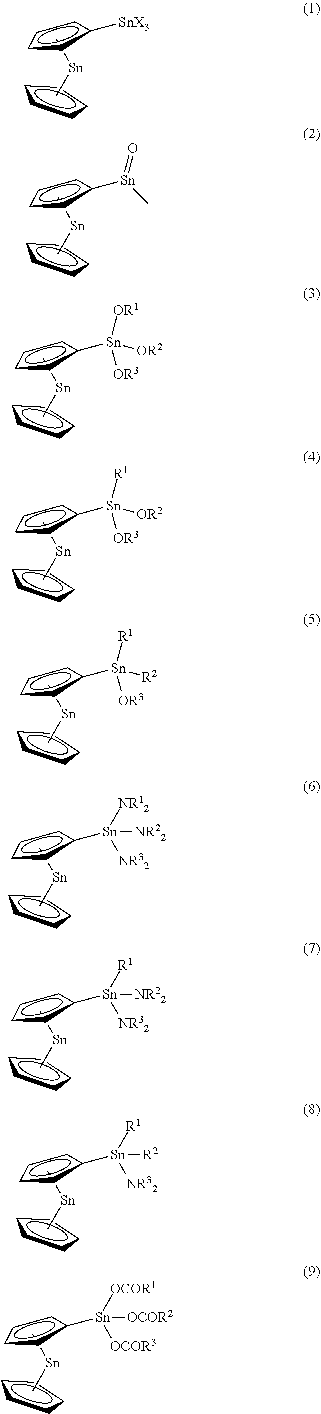

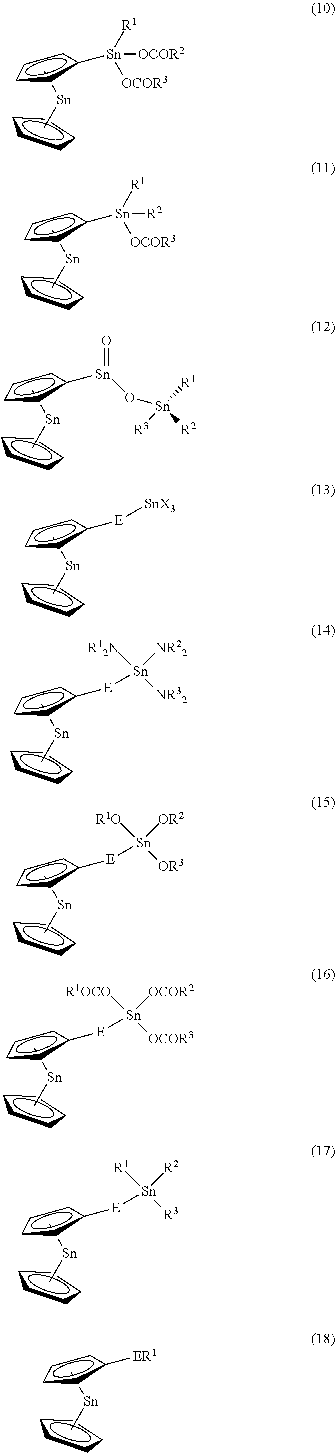

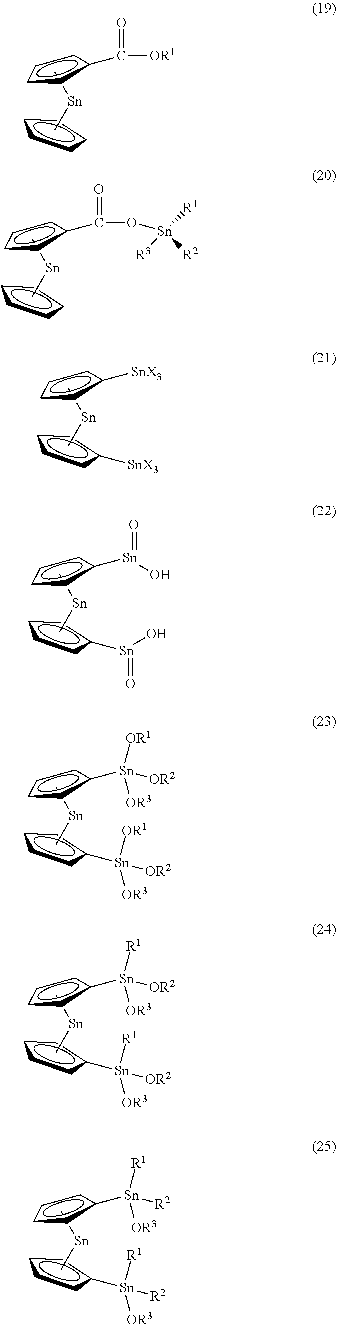

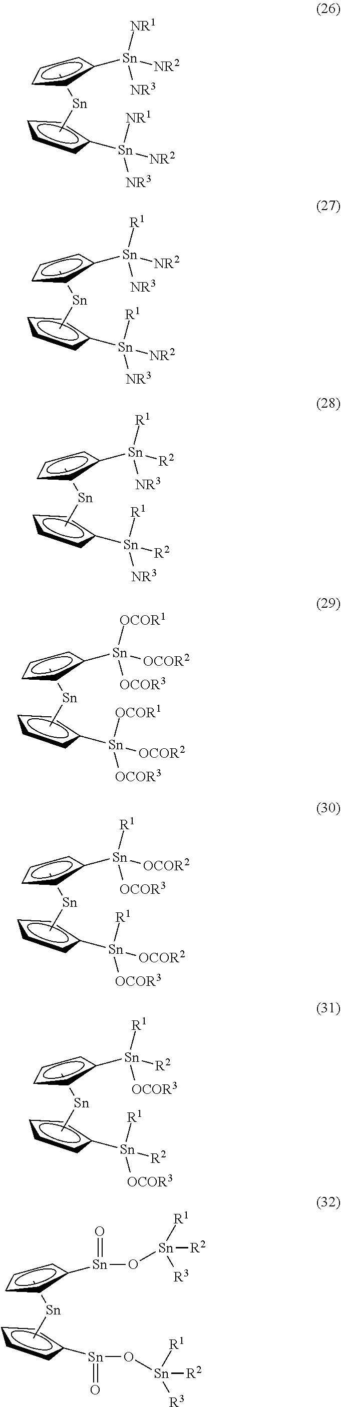

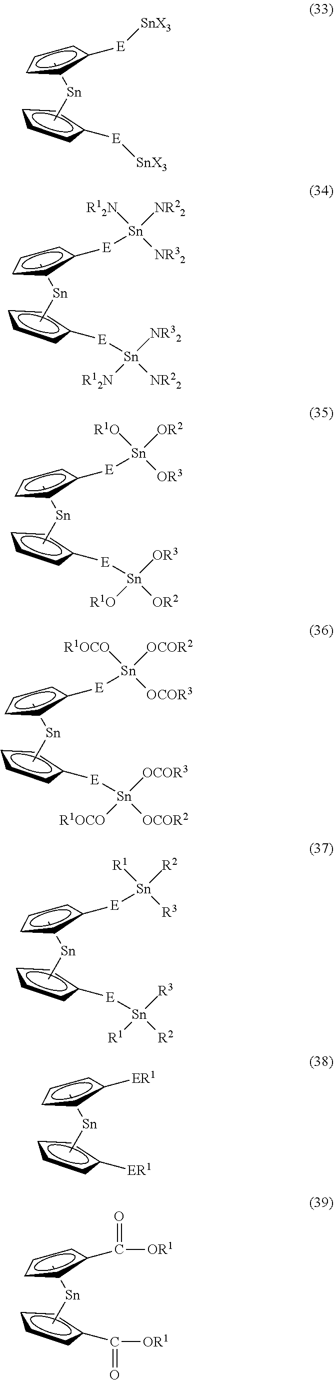

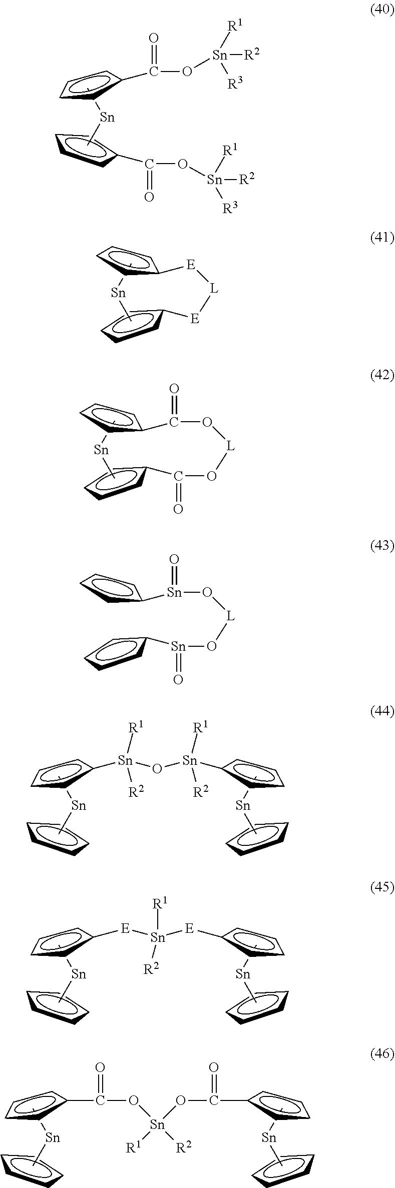

wherein R¹, R², R³, are each independently H, substituted or unsubstituted linear or branched alkyl, alkenyl, alkynyl, cycloalkyl, or cycloalkenyl group with 1 to 20 carbon atoms, or substituted or unsubstituted aryl group with 6-20 carbon atoms;
E=O, S, Se, or Te; X=F, Cl, Br, or I;
L is a linear or branched alkyl, alkenyl, alkylene, alkynyl, or cycloalkyl group with 1 to 20 carbon atoms, or an aryl group with 6-20 carbon atoms, or an amino, cyano, ether, ester, halide, nitro, silyl, thiol, or carbonyl group.

For example, R¹, R², R³ are independently methyl, ethyl, propyl, isopropyl, n-butyl, i-butyl, t-butyl, pentyl, hexyl, cyclopentyl, cyclohexyl, or cyclopentadienyl group; E=O, S, Se or Te; X=Cl, L is methylene, ethylene, or propylene.

In some embodiments, (stannocenyl)tin compound photoresists may comprise various functional groups, including but not limited to, ether, thiol, silyl, keto, cyano, carbonyl, halogen, or combinations thereof.

In some embodiments, (stannocenyl)tin compound photoresists possess the hapticity of η¹, η², η³, η⁴, or η⁵ of isomers.

Hereinafter, cycloalkenyl group comprises a substituted and unsubstituted C4 to C8 aliphatic unsaturated organic groups including at least one double bond, for example, cyclopentadienyl, or cycloheptatrienyl.

In some embodiments, (stannocenyl)tin compound photoresists according to embodiments of the present disclosure may be represented by at least one of examples. Examples of specific (stannocenyl)tin compound photoresists or precursors that may be used in implementations of the invention are represented by the Chemical Formulas (1)-(46).

In the present disclosure, organometallic sandwich bis(cyclopentadienyl)tin (stannocene, or Sc) is used as parent molecule to synthesize (stannocenyl)tin compounds. Stannocene is synthesized according to the reference: C. Janiak, Zeitschrift fUr Anorganische und Allgemeine Chemie, 2010, 636 (13-14), 2387-2391. The product is purified by sublimation under high vacuum as pale yellow crystals. In some embodiments, lithiation of stannocene at one or two C₅ rings is applied to synthesize (stannocenyl)tin compounds, such as mono-lithiation, or bi-lithiation with strong bases, for example, methyllithium (MeLi), n-butyllithium (n-BuLi), or t-butyllithium (t-BuLi), then followed by further procedures to synthesize relevant derivatives, for example, represented by the Chemical Formulas (1)-(46).

In some embodiments, organometallic sandwich stannocene can be carried out multi-lithiation at one or two C₅ rings, which may depend on the amount of strong base and reaction condition. A person of ordinary skills in the art will recognize that the synthetic strategies, reagents, or reaction conditions including reactant ratios, temperature, reaction time, or addition manner within the explicit ranges of above are contemplated and are within the present disclosure.

In an example embodiment, mono-lithiation at one C₅ ring of stannocene is carried out at −78° C. in THF by t-BuLi in the presence of KO^{t}Bu to afford (η⁵—C₅H₅)Sn(η⁵—C₅H₄Li) (ScLi) as Scheme 1 depicted. A person of ordinary skills in the art will recognize that the synthetic strategies, reagents, or reaction conditions including reactant ratios, temperature, reaction time, or addition manner within the explicit ranges of above are contemplated and are within the present disclosure.

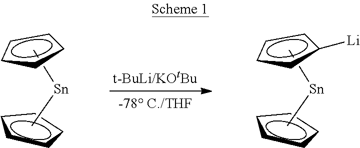

In another example embodiment, mono-substituted-C5 ring (stannocenyl)tin compounds are synthesized as Scheme 2 depicted, including but not limited to, under ambient conditions. A person of ordinary skills in the art will recognize that the synthetic strategies, reagents, or reaction conditions including reactant ratios, temperature, reaction time, or addition manner within the explicit ranges of above are contemplated and are within the present disclosure.

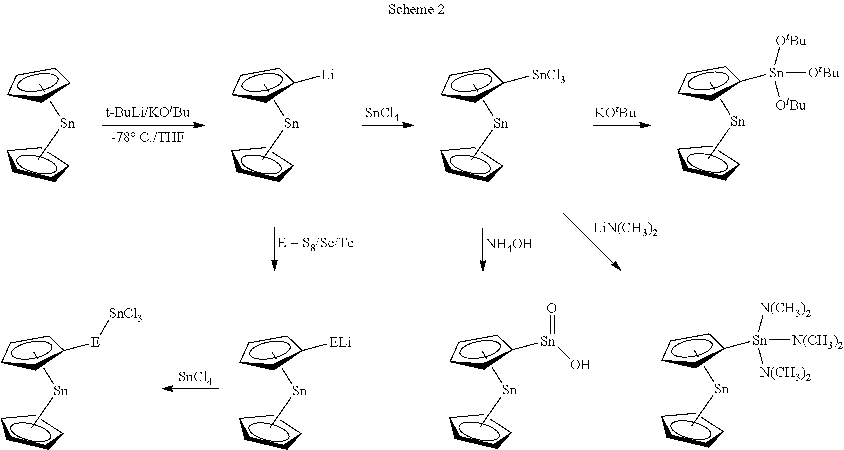

In an example embodiment, bi-lithiation at two C₅ rings of stannocene is carried out by n-BuLi at −78° C. in THF to afford (η⁵—C₅H₄Li)Sn(η⁵—C₅H₄Li) (ScLi₂) as Scheme 3 depicted, which is according to the references, A. H. Cowley, P. Jutzi, F. X. Kohl, J. G. Lasch, N. C. Norman, E. Schluter, “Sequential Lithiation and Silylation of Stannocene”, Angew. Chemie International Edition 23 (1984), 8, 616-617; A. H. Cowley, J. G. Lasch, N. C. Norman, C. A. Stewart, and T. C. Wright, “Lithiation and Derivatization of Group 4 Å Bent-Sandwich Molecules”, Organometallics 1983, 2, 1691-1692, all of which are incorporated herein by references. In some embodiments, the addition of coordination reagents is required to improve the yields of bi-lithiation at two C₅ rings, for example, (N,N,N′,N′-tetramethyl-1,2-diaminotheane (TMEDA). A person of ordinary skills in the art will recognize that the synthetic strategies, reagents, or reaction conditions including reactant ratios, temperature, reaction time, or addition manner within the explicit ranges of above are contemplated and are within the present disclosure.

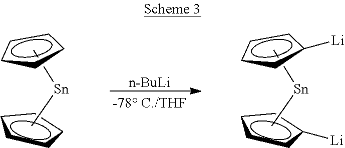

In another example embodiment, the represented bi-substituted (stannocenyl)tin compounds are prepared, as Scheme 4 depicted, through the reactions of (η⁵—C₅H₄Li)Sn(η⁵—C₅H₄Li) (ScLi₂) with appropriate reagents under ambient conditions, including, but not limited to. A person of ordinary skills in the art will recognize that the synthetic strategies, reagents, or reaction conditions including reactant ratios, temperature, reaction time, or addition manner within the explicit ranges of above are contemplated and are within the present disclosure.

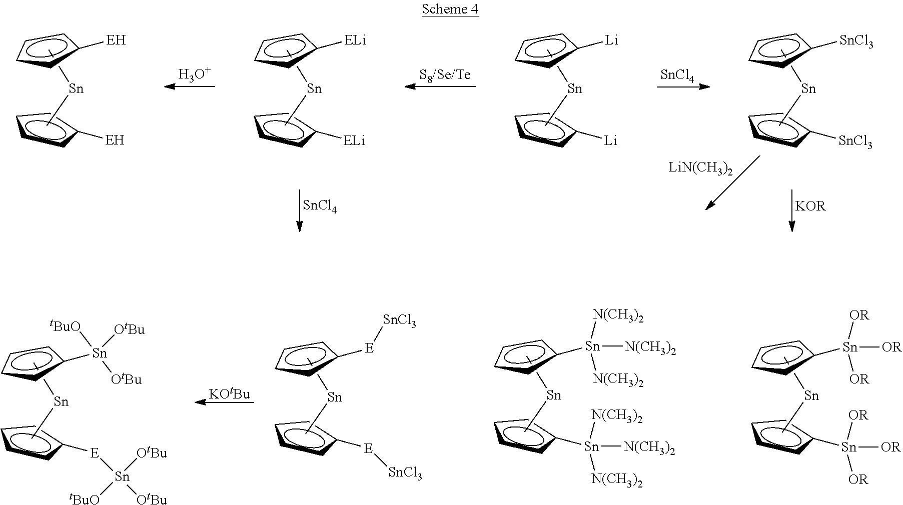

In one example embodiment, stannocenol (η⁵—C₅H₅)Sn(η⁵—C₅H₄OH) or (η⁵—C₅H₄OH)₂Sn can be prepared by the reactions of (η⁵—C₅H₅)Sn(η⁵—C₅H₄Li) or (η⁵—C₅H₄Li)₂Sn with (CH₃)₃SiOOSi(CH₃)₃ at −78° C. in THF, respectively, then followed by acidification or hydrolysis as Scheme 5 depicted, which is according to the similar manner of the reference, C. Elschenbroich, F. Lu, H. Klaus, “[5]Trovacenol, (η⁷—C₇H₇)V(η⁵—C₅H₄OH): Synthesis and Structural Characterization”, Organometallics, 2002, 21 5152-5154, which is incorporated herein by reference. In some embodiments, (η⁵—C₅H₅)Sn(η⁵—C₅H₄OH) or (η⁵—C₅H₄OH)₂Sn may react with bases, for example, NaOH or n-BuLi, to form (η⁵—C₅H₅)Sn(η⁵—C₅H₄ONa) or (η⁵—C₅H₄OLi)₂Sn, which may be used as the precursors for the further synthesis of organotin compounds. A person of ordinary skills in the art will recognize that the synthetic strategies, reagents, or reaction conditions including reactant ratios, temperature, reaction time, or addition manner within the explicit ranges of above are contemplated and are within the present disclosure.

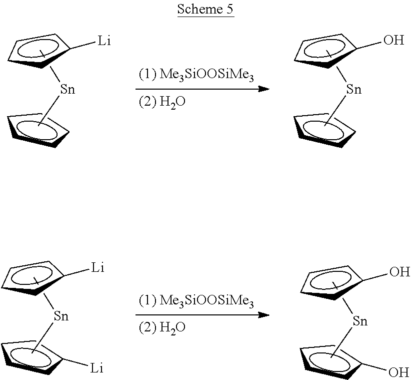

In one example embodiment, (stannocenyl)chalcogenide and related derivates are prepared according to the similar manner of the references, C. Elschenbroich, F. Lu, K. Harms, O. Burghaus, “Synthesis, electrochemical behavior and EPR study of organometallic [5]trovacenylthiol (η⁷—C₇H₇)V(η⁵—C₅H₄SH) and structural characterization of ansa-trithio[3]trovacenophane”, Journal of Organometallic Chemistry, 755 (2014) 58-63; C. Elschenbroich, F. Lu, O. Burghaus, K. Harms, J. Pebler, “Bis([5]trovacenyl)dichalcogenides: Synthesis, Structure, and Study of Intramolecular Communication”, Zeitschrift fUr Anorganische und Allgemeine Chemie, 2011, 637, 1750-1755; C. Elschenbroich, F. Lu, K. Harms, O. Burghaus, C. Pietzonka, J. Pebler, “α,ω-Di([5]trovacenyl) Sulfides TVC-Sn-TVC (n=1-4) and TVC-SCH₂S-TVC: a Study in Intramolecular Communication”, European Journal of Inorganic Chemistry, 2012, 3929-3936; F. Lu, “Elemental sulfur as soft oxidant for facile one-pot preparation of air-sensitive organometallic di[5]trovacenyldichalcogenides”, Inorganic Chemistry Communication, 37 (2013) 148-150; all of which are incorporated herein by references. A person of ordinary skills in the art will recognize that the synthetic strategies, reagents, or reaction conditions including reactant ratios, temperature, reaction time, or addition manner within the explicit ranges of above are contemplated and are within the present disclosure.

In one example embodiment, stannocenyl carboxylic acid (η⁵—C₅H₅)Sn(η⁵—C₅H₄COOH) or (η⁵—C₅H₄COOH)₂Sn (as Scheme 6 depicted) are synthesized by the reactions of (η⁵—C₅H₅)Sn(η⁵—C₅H₄Li) or (η⁵—C₅H₄Li)₂Sn with gaseous CO₂ to afford intermediates (η⁵—C₅H₅)Sn(η⁵—C₅H₄COOLi) or (η⁵—C₅H₄COOLi)₂Sn, respectively, then followed by acidified by HCl solution, which is according to the similar manner of the reference, C. Elschenbroich, O. Schiemann, O. Burghaus, and K. Harms, “Exchange Interaction Mediated by O—H—O Hydrogen Bonds: Synthesis, Structure, and EPR Study of the Paramagnetic Organometallic Carboxylic Acid (η⁷—C₇H₇)V(η⁵—C₅H₄COOH)”, Journal of the American Chemical Society, 1997, 119, 7452-7457, which is incorporated herein by reference. In some embodiments, the as-formed intermediate (η⁵—C₅H₅)Sn(η⁵—C₅H₄COOLi) or (η⁵—C₅H₄COOLi)₂Sn may be used as the precursors for the further synthesis. A person of ordinary skills in the art will recognize that the synthetic strategies, reagents, or reaction conditions including reactant ratios, temperature, reaction time, or addition manner within the explicit ranges of above are contemplated and are within the present disclosure.

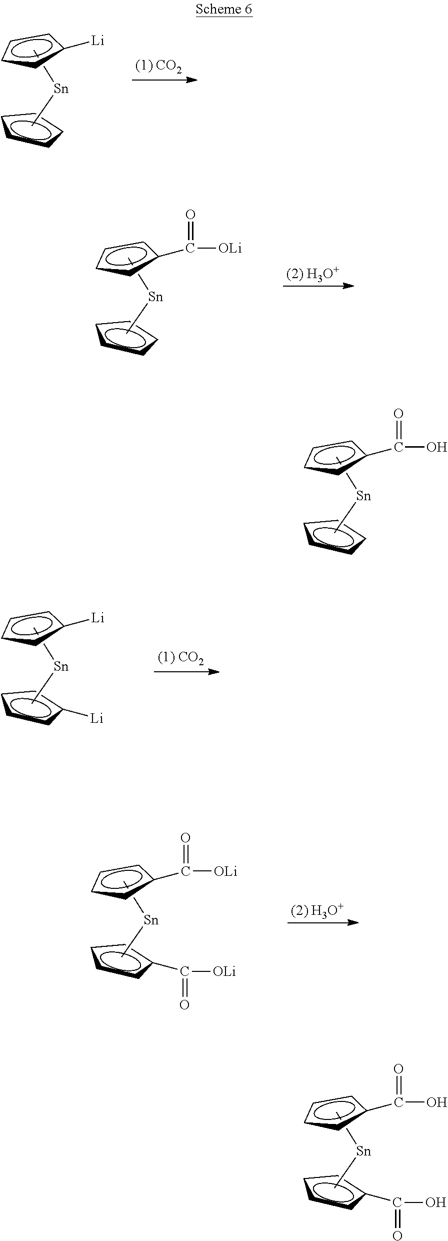

In the present disclosure, the purification methods include, but not limited to, distillation, extraction, filtration, recrystallization, column chromatography, coordination and sublimation, and combinations thereof. For example, recrystallization can be carried out by slowly cooling down the hot solution of compounds to ambient temperature (e.g., room temperature or lower). The solvents for recrystallization include, but not limited to, hexane, petroleum ether, diethyl ether, THF, benzene, toluene, ethanol, or combinations thereof. In some embodiments, recrystallization may result in single crystals, which are suitable for X-ray diffraction analysis for determining the related molecular structures. The column chromatography is usually carried out with silicon or aluminum oxide under air or inert atmosphere. In some embodiments, a short pad column is applied for fast purification of the products. In some embodiments, fractional distillation is used to purify the liquid products under reduced pressure. In some embodiments, sublimation can be conducted under high vacuum and temperature without decomposition.

In addition, (stannocenyl)tin compounds represented by the Chemical Formulas (1)-(46) may be applied as the precursors for the formation of photolithographic latent pattern over a substrate.

For example, in some embodiments, (stannocenyl)tin compounds may be applied as the precursors reacting with oxygen-source atmosphere, such as air or oxygen (O₂), ozone (O₃), hydrogen peroxide (H₂O₂), or water (H₂O) to form photoresists (such as organotin clusters) or pattern film over the substrate for photolithography patterning, which can result in or enhance oxidization of irradiated organotin photoresist to form metal oxide or polymetallic oxide networks under some circumstances.

In some embodiments, (stannocenyl)tin compound may act as first precursor to react with second precursor such as reactive gaseous atmosphere H₂S, SO₂, S₈, CO₂, CO, HCOOH, NH₃, PH₃, or SiH₄, and then form the photoresist layer over the substrate for photolithography patterning. This may increase the contrast between irradiated and unirradiated portions of organotin photoresists.

In some embodiments, organotin clusters are used as EUV photoresist, which are light-sensitive, but may not be volatile for sublimation or vaporization. As a result, after exposed to EUV light, the unexposed portion may not be efficiently removed by wet development liquid solvents due to wetting and surface tension at smaller size like 1˜3 nm pitch.

In some embodiments, the sublimation or vaporization development method may also be applied for >10 nm patterning, such as deep ultraviolet radiation (DUV), far ultraviolet (FUV). The residual, radiated, or unirradiated photoresist between pattern features may be removed. This requires radiation sensitive (stannocenyl)tin compound photoresist at the levels which are suitable for DUV or FUV, according to E=hy=hc/λ and BDE (M-C), wherein E represents energy, h is plank constant, v is frequency, c is light speed and X is light wave length. For example, the unexposed portion of organotin photoresists can be removed by sublimation or vaporization under high vacuum and temperature for patterning after exposure to ultraviolet.

In some embodiments, upon exposing to actinic radiation, a blend of (stannocenyl)tin compound photoresists may be carried out in situ ultraviolet light-induced radiation reaction to form non-sublimized, non-volatile or insoluble complexes, for example, oxo/hydroxyl, polyatomic complexes, metal oxo or hydroxyl network, or organometallic polymer, which possess the feature characterizes for small pitch like <7 nm. The unexposed portion of (stannocenyl)tin compound photoresists may be removed by sublimation or vaporization under vacuum ranging from 0.0001 torr to 100 torr and temperature ranging from 20° C. to 300° C. In some embodiments, the in situ radiation reaction may be carried out in solvents like organic solvent, which is spray on the substrate surface after deposition of (stannocenyl)tin compound photoresist, or by spinning-on deposition as solution composition.

In some embodiments, a blend of organometallic compound photoresists may have identical or different metal centers with M-C bond. The metals include, but not limited to, Sn, In, Sb, Bi, Mn, V, Ti, Cr, Se, Te, Zr, Hf, Ga, or Ge, for example, sandwich, or half-sandwich organometallic compounds.

In some embodiments, a blend of organometallic compound photoresist [M1] with organometallic photoresist [M2], or more like, will perform ultraviolet light-induced reaction. In some embodiments, M-M′ or M-O-M′ bond may form upon ultraviolet radiation and may have poor solubility in organic solvent or neutral, basic or acidic aqueous solution, and lack of volatility under high vacuum and ambient temperature, wherein M, or M′ represent metal atoms of [M1], or [M2].

For example, upon exposing, organometallic compound photoresist [M1] reacts with [M2] through hydrolysis or condensation to form a coating film comprising metal oxides or oxo/hydroxyl networks, which are not available for sublimation or vaporization under ambient vacuum and temperature. On the contrary, the unexposed organometallic photoresist [Ml] and [M2] can be removed by sublimation or vaporization under ambient vacuum and temperature to form the desired patterns without collapses or defects.

In general, EUV photolithography process is (1) depositing photoresist as a thin film; (2) then pre-exposure baking; (3) followed by exposing to EUV radiation to form a latent image; (4) after post-exposure baking; (5) then developing with a liquid such as aqueous basic/acid solutions or organic solvents; (6) and then rinsing with solvent to produce the developed resist pattern. This processing method is applicable for >10 nm pitch like 30-60 nm. However, for <10 nm pitch pattern structures, sublimation and vaporization development methods may avoid the usage of plenty of solvents and related waste treatments, and reduce cost and environment concerns.

Wet and dry deposition or coating methods may be carried out over the surface of semiconductor substrate. The general wet coating of radiation sensitive organometallic photoresists on the surface of semiconductor substrate includes spin-on coating, spray coating, dip coating, vapor deposition, knife edge coating, inkjet printing, screen printing, or the like.

In some embodiments, the conventional spin-on coating method is used for deposition of organometallic photoresists on the surface of semiconductor substrates to form a thin film for photolithography. Under this circumstance, the followed procedure of post-apply backed (PAB) on a hot plate at ambient temperature like 100 C.° under inert atmosphere (e.g., dinitrogen) with regular pressure will be controlled to avoid the potential photoresist sublimation at the point temperature, and then decrease the thickness of photoresist, followed by defects generation or pattern collapses.

In some embodiments, organometallic photoresists may be deposited over semiconductor substrate through dry deposition method, such as chemical vapor deposition, physical vapor deposition, or atomic layer deposition without decomposition.

In some embodiments, the advantages of chemical vapor deposition or atomic layer deposition methods may improve the uniformity of thickness and composition, reduce the photoresist film defect density.

In some embodiments, (stannocenyl)tin compounds may be suitable for chemical vapor deposition or atomic layer deposition to form metal oxide film through photolithography patterning.

In some embodiments, (stannocenyl)tin compounds may be sublimized or vaporized over the substrate under high vacuum and temperature, rather than decomposition. This is different from conventional deposition by decomposition through chemical vapor deposition, physical vapor deposition, or atomic layer deposition method.

The development process is to remove either the exposed portion to form the positive tone pattern, or unexposed portion to form negative tone pattern by different developer compositions. The contact of the pattered coating material or latent image with developer solvents will perform the target.

In some embodiments, the conventional wet development process with organic solvents or aqueous solutions, for example, dipped in conventional 2-heptaone bath for forty seconds to remove unexposed portions of photoresist film to develop a negative-tone pattern, may be replaced by sublimation or vaporization under high vacuum and appropriate temperature, which can reduce the pattern collapse. For <7 nm pitch pattern, due to wetting and solvent surface tension effect, the wet development may not be efficient to remove unexposed portion of photoresist between two adjacent pitches at small sizes.

In additional embodiment, the rinse process after development, for example, the treatment of patterned film by aqueous tetramethylammonium hydroxide (TMAH) solution for 10-30 seconds, may be omitted. Furthermore, no wet solvent development and rinse process may reduce the cost and pollution, improve the resolution efficiency of pattern, and protect the environment.

In some embodiments, the general wet developer compositions can be neutral, basic, acidic aqueous solutions, or organic solvents at low to high concentrations. The temperature for development process can be high or low. The temperature can be applied for the control of the rate or kinetics of development process as required.

In some embodiments, the general wet liquid solvent developer composition comprises an organic solvent blend. Non-limiting examples of organic solvents used in the method of forming patterns according to an embodiment may include, but not limited to, ketones (e.g., acetone, 2-heptanone, methylethylketone, cyclohexanone, 2-pyrrolidone, 1-ethyl-2pyrrolidone, and/or the like), alcohols (e.g., methanol, ethanol, 1-propanol, isopropanol, 1-butanol, 4-methyl-2-propanol, 1,2-propanediol, 1,2-hexanediol, 1,3-propanediol, pentanol, 2-heptanol, and/or the like), esters (e.g., ethyl acetate, n-butyl acetate, butyrolactone, propylene glycol methyl ether, ethylene glycol, propylene glycol, glycerol, ethylene glycol methyl ether, and/or the like), aromatic solvents (e.g., benzene, toluene, xylene), acid (e.g., formic acid, acetic acid, oxalic acid, 2-ethylhexanonic acid), and combinations thereof.

In some embodiments, the wet liquid solvent developing process is applied by dipping the exposed/unexposed substrates into a developer bath. In some embodiments, the wet solvent developing solution can be sprayed into the exposed/unexposed photoresists layer.

In some embodiments, after development, the formed pattern coating can be heated to the range of 100-600° C. without pattern collapse. The heat can be carried out under air, inert atmosphere, or in vacuum.

In some embodiments, for the patterned pitch <7 nm, it will be difficult to remove the unexposed portion of photoresists by liquid solvents due to the high aspect ratio of thickness/pitch. The wetting, surface tension or distorting force would make the conventional wet development unlikely due to the small space between two adjacent pitches, along with structure pattern collapses and defects.

In some embodiments, radiation sensitive organometallic photoresists possessing sublimation or vaporization ability are represented by RₐM_{b}L_{c}, wherein, R is organic group with high radiation sensitivity in the radiation range, including, but not limited to alkyl, alkenyl, alkynyl, cycloalkyl, or cycloalkenyl group, for example, cyclopentadienyl; M is metal, such as Sn, In, Sb, Bi, Mn, V, Ti, Cr, Se, Te, Zr, Hf, Ga, Ge; L is hydrolysable ligand containing functional groups, including, but not limited to, hydroxide, amine, amide, ester, halide, nitride, oxide, or thiolate; and a, b, c≥1. For example, (cyclopentadienyl)tin, (cyclopentadienyl)indium, (cyclopentadienyl)antimony, or (cyclopentadienyl)vanadium compounds.

The desired features of organotin photoresists or precursors possess, (1) sufficient volatility or sublimation ability for vapor phase transportation, (2) thermal stability to avoid the premature decomposition, and (3) appropriate reactivity with co-precursor to form the target product in the presence of UV or EUV light radiation.

In the present disclosure, the invention pertains to a method of developing a photolithography pattern by sublimation or vaporization, comprising: (1) forming an organotin photoresist solution composition; wherein the forming the organotin photoresist solution composition comprises: (stannocenyl)tin compound, a solvent, and/or an additive; (2) depositing organotin photoresist solution composition on a surface of the substrate to form a photoresist layer for photolithography patterning; (3) exposing organotin photoresist layer to actinic radiation to form a latent pattern; and (4) developing the latent pattern by applying sublimation or vaporization method to remove unexposed organotin photoresist to form a photolithography pattern.

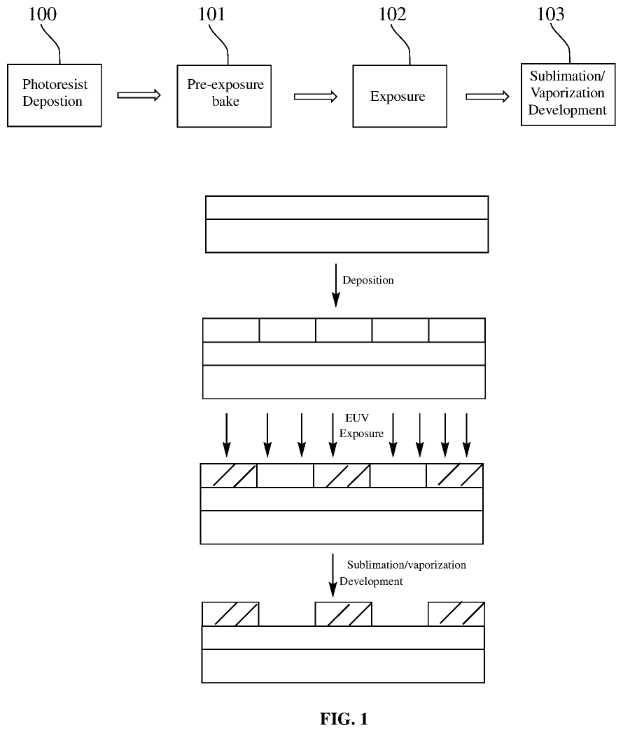

FIG. 1 is a flowchart of photolithography patterning processing including organotin photoresists depositing over a substrate 100; in some embodiments, followed by pre-exposure baking 101; then exposing photoresist to actinic radiation (e.g., EUV) to form latent pattern 102; and then developing the formed latent pattern by sublimation or vaporization development 103.

In the present disclosure, organotin photoresist composition for photolithography patterning comprises (stannocenyl)tin compound, a solvent, and/or an additive.

The composition of organometallic (stannocenyl)tin compound photoresist according to embodiments of the present disclosure may have improved etch resistance, sensitivity and resolution, compared with conventional organic polymer or inorganic resists, wherein carbon, oxygen, nitrogen, or various groups are bonded to tin metal.

In some embodiments, (stannocenyl)tin compound photoresists are soluble in appropriate organic solvents for further photolithography pattern processing. The solution compositions can be formed by dissolving (stannocenyl)tin compound photoresists in organic solvents, e.g., chloroform, tetrahydrofuran, dimethoxyethane, dimethylformamide, dimethyl sulfoxide, alcohols (e.g., 4-methyl-2-pentenol, ethanol, methanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like.

In some embodiments, the solubility of (stannocenyl)tin compound photoresists in organic solvents may be improved, and dissolution during extreme ultraviolet exposure. Accordingly, a nanoscale pattern having improved sensitivity and limited resolution may be afforded. Additionally, the as-formed pattern may not collapse while having a high aspect ratio.

In some embodiments, (stannocenyl)tin compound photoresists composition may also contain additives, including, but not limited to, organic stabilizer, densifier, or resin.

In some embodiments, the organic stabilizer comprises organic thiol, organic alcohol, organic amine, organic amide, organic carboxylic acid, organic phosphine, organic phosphine oxide, organic phosphonic acid, or a combination thereof.

In some embodiments, the resin may be organic polymer, or small organic aromatic molecules. In some embodiments, the resin may be volatile under ambient vacuum and temperature.

After exposure to actinic radiation, the exposed and unexposed portion possess different chemical and physical properties. For example, the exposed portion converts to metal oxide without liability for sublimation or vaporization. However, the unexposed portion still possesses the volatility property and may be removed by sublimation or vaporization under high vacuum and temperature without decomposition or pattern collapse. The sublimation or vaporization method avoids the application of wet and dry developer, and/or rinse process, improves the resolution, and reduces the pattern collapse.

In some embodiments, after exposure, (stannocenyl)tin compound photoresists absorb the ultraviolet radiation. Organic ligand groups can be cleaved from (stannocenyl)tin compound photoresists to form metal oxide or polymetallic oxide/oxo pattern. The unexposed portion over the substrate surface may be removed by sublimation or vaporization without pattern collapses and defects.

The sublimation or vaporization development method avoids the disadvantages of wet development methods, such as dipping in organic solvents or aqueous solutions for development, washing by solvents for removal, potential pattern collapses and defects due to the washings, relatively higher cost, waste solvents treatment, or environmental concerns like pollution control.

The properties of organotin photoresists determine the availability of sublimation or vaporization development method, wherein (stannocenyl)tin compound photoresists can be sublimized or vaporized under vacuum ranging from 0.0001 torr to 100 torr, and temperature ranging from 20 to 300° C. without decomposition. (Stannocenyl)tin compound photoresist possess radiation sensitive for photolithography patterning. The exposed portion of (stannocenyl)tin compound photoresist converts to metal oxides or polymetallic oxide networks, which cannot be removed by sublimation or vaporization under ambient vacuum and temperature.

The sublimation or vaporization development method may enhance pattern fidelity, and eliminate microbridge defects, due to no usage of liquid solvent or gaseous.

The sublimation or vaporization development method may significantly improve the efficiency, resolution and products ratios, and reduce the cost including environmental concerns and waste treatment like water consuming, waste water/organic solvent treatment.

The features of radiation sensitive (stannocenyl)tin compound photoresists, such as sublimation or vaporization ability and thermostability without decomposition under high vacuum and temperature, play the key role in determining the development method with particular stability and processing effectiveness for radiation absorption.

In some embodiments, (stannocenyl)tin compound photoresists expose to ultraviolet light, such as EUV or DUV, under inert atmosphere (e.g., dinitrogen or argon) or normal pressure, in order to avoid the potential sublimation or vaporization, or pattern collapses and defects.

In some embodiments, the exposed (stannocenyl)tin compound photoresist may be carried out radiation-induced oxidation or hydrolysis in the presence of oxygen source, such as oxygen (O₂), ozone (O₃), hydrogen peroxide (H₂O₂), or water (H₂O), during actinic radiation, and convert to oxide, oxo, or hydroxyl network products. Unexposed portion may be removed by sublimation or vaporization under high vacuum and temperature.

In some embodiments, the exposed portion of (stannocenyl)tin compound photoresist can be conducted by dry etch processing using dry BCl₃ plasma, hydrogen halides (HX), hydrogen gas (H₂), or halogen gas.

In addition, (stannocenyl)tin compound photoresists for photolithography patterning according to an embodiment is not necessarily limited to the negative tone image, but may be formed to have a positive tone image.

Hereinafter, the present invention is described in more details through Examples regarding the preparation of (stannocenyl)tin compounds of the present embodiments. The synthetic strategy, reagent, reaction manner, or reaction condition determine the molecular structures of (stannocenyl)tin compounds with the hapticity of η¹, η², η³, η⁴ or η⁵ of isomers. However, the present invention is not limited by the Examples.

### EXAMPLES

### Example 1

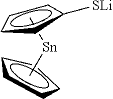

This example and the followings provide the solid evidences for the synthesis of organotin compounds. The Schlenk lines with stand techniques like dried organic solvents under dried inert dinitrogen or argon atmosphere are utilized for the synthesis and purification of organotin compounds. Bis(cyclopentadienyl)tin or stannocene (Sc) as parent molecule was synthesized according to the reference: C. Janiak, Zeitschrift fUr Anorganische und Allgemeine Chemie, 2010, 636 (13-14), 2387-2391. The product was purified by sublimation under high vacuum as pale yellow crystals.

Synthesis of (η⁵—C₅H₅)Sn(η⁵—C₅H₄SLi) (Sc—SLi). Sc—SLi was prepared according to the similar manner of the reference: C. Elschenbroich, F. Lu, O. Burghaus, K. Harms, and J. Pebler, Zeitschrift fUr Anorganische und Allgemeine Chemie, 2011, 637, 1750-1755. (η⁵—C₅H₅)Sn(η⁵—C₅H₄Li) (ScLi) was prepared from the reaction of stannocene with t-BuLi in the presence of KO^{t}Bu in THF at −78° C. To a solution of (η⁵—C₅H₅)Sn(η⁵—C₅H₄Li) (Sc—Li) (from 762 mg, 3.06 mmol stannocene, 2.0 mL/1.6 M t-BuLi) in diethyl ether (60 mL) at −20° C., freshly sublimized S₈ powder (98 mg, 3.06 mmol) was added with vigorously stirring. After stirring at room temperature overnight, all the volatiles were removed in vacuum to afford the titled product. Yield: 790 mg, 90%.

### Example 2

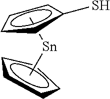

Synthesis of (η⁵—C₅H₅)Sn(η⁵—C₅H₄SH). At 0° C., to a solution of Sc—SLi (292 mg, 1.02 mmol) in 30 mL dimethoxyethane (DME), HCl (2 mL, 15%) was added. The mixture was stirred at room temperature for one hour, and was dried over MgSO₄, and filtered through Celite. The filtrate was evaporated in vacuum to give the titled product. Yield: 260 mg, 90%. ¹H NMR (400.13 MHz, CDCl₃) δ=6.16 (s, 5H), 6.32 (m, 2H), 6.61 (m, 2H). MS (EI): m/z 281 (M⁺). Elemental analysis of C₁₀H₁₀SSn (394.89), anal. calculated C: 42.77%; H: 3.56; and found C: 42.92; H, 3.88.

### Example 3

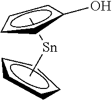

Synthesis of (η⁵—C₅H₅)Sn(η⁵—C₅H₄OH) (Sc—OH). Sc—OH was prepared by the reaction of ScLi with Me₃SiOOSiMe₃ at −78° C., which was according to the similar manner of the reference: C. Elschenbroich, F. Lu, and H. Klaus, Organometallics, 2002, 21 5152-5154. At −78° C., to a solution of ScLi (from 573 mg, 2.3 mmol stannocene) in Et₂O (50 mL), Me₃SiOOSiMe₃ (0.5 mL, 2.3 mmol) was added with vigorously stirring. The mixture was warmed slowly to room temperature and stirred overnight. Water (1 mL) was added. After one hour, the organic phase was separated and dried over MgSO₄, and filtered over Celite. The filtrate was evaporated in vacuum and the reside was extracted by hexane. The extraction was filtered through Celite. The filtrate was evaporated in vacuum to give the titled product. Yield: 366 mg, 60%. ¹H NMR (400.13 MHz, C₆D₆) δ=5.96 (s, 5H), 6.12 (m, 2H), 6.35 (m, 2H). MS (EI): m/z 265 (M⁺).

### Example 4

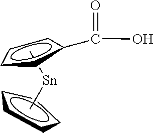

Synthesis of (η⁵—C₅H₅)Sn(η⁵—C₅H₄COOH) (Sc—COOH). Sc—COOH was prepared by the reaction of ScLi with CO₂ followed by acidification, which was according to the similar manner of the reference: C. Elschenbroich, O. Schiemann, O. Burghaus, and K. Harms, Journal of the American Chemical Society, 1997, 119, 7452-7457. To a solution of Sc—Li (from 651 mg, 2.6 mmol stannocene) in Et₂O (50 mL) at −20° C., gaseous CO₂ was introduced with vigorously stirring. After stirring at room temperature for hours, the solvent was removed in vacuum, and the reside was dissolved in H₂O. Then the mixture was acidified by aqueous HCl solution (15%) to afford precipitate, which was collected and dried in vacuum. Yield: 580 mg, 76%. ¹H NMR (400.13 MHz, CDCl₃) δ=5.81 (s, 5H), 5.73 (m, 2H), 5.90 (m, 2H). MS (EI): m/z 293 (M⁺).

### Example 5

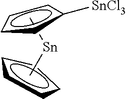

Synthesis of (η⁵—C₅H₅)Sn(η⁵—C₅H₄SnCl₃) (Sc—SnCl₃). At −78° C., the solution of ScLi (from 2.48 g, 10 mmol stannocene) in Et₂O (50 mL) was added dropwise to a solution of SnCl₄ (1.36 mL, 10 mmol) in hexane (100 mL) in one hour with vigorously stirring (Caution: SnCl₄ is extremely hydrolytic when exposure to air or water and releasing HCl gaseous !!!). After stirring for hours, the mixture were filtered through Celite. The filtrate was evaporated in vacuum to give the titled product. Yield: 72%. MS (EI): m/z 473 (M⁺).

### Example 6

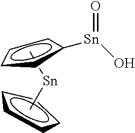

Synthesis of (η⁵—C₅H₅)Sn[(η⁵—C₅H₄)SnO(OH)]. Deoxygenized aqueous ammonium hydroxide solution (30 mL) was added to Sc—SnCl₃ (516 mg, 1.09 mmol) at room temperature with vigorous stirring. After stirred for 2 hours, the obtained precipitate was filtered and washed with DI water (3×10 mL). The solid was dried in vacuum overnight to afford the titled product. Yield: 218 mg, 50%. MS (EI): m/z 400 (M⁺).

### Example 7

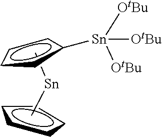

Synthesis of (η⁵—C₅H₅)Sn[(η⁵-C₅H₄)Sn(O^{t}Bu)₃]. To the solution of Sc—SnCl₃ (455 mg, 1.13 mmol) in toluene (60 mL) at 0° C., ^{t}BuOK (380 mg, 3.39 mmol) was added and the mixture was stirred at room temperature overnight, then followed by filtration through Celite. The filtrate was evaporated in vacuum to afford the product. Yield: 463 mg, 70%. ¹H NMR (400.13 MHz, CDCl₃) δ=1.36 (s, 27H), 6.12 (s, 5H), 6.26 (m, 2H), 6.68 (m, 2H). MS (EI): m/z 586 (M⁺). Elemental analysis of C₂₂H₃₆O₃Sn₂ (585.64), anal. calculated C: 45.12%; H: 6.15; and found C: 45.60; H, 6.36.

### Example 8

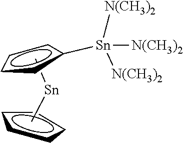

Synthesis of (η⁵—C₅H₅)Sn[(η⁵—C₅H₄)Sn(N(CH₃)₂)₃]. To the solution of Sc—SnCl₃ (462 mg, 1.16 mmol) in toluene (50 mL) at 0° C., LiN(CH₃)₂ (178 mg, 3.5 mmol) was added. The mixture was stirred at room temperature overnight, then followed by filtration through Celite. The filtrate was evaporated in vacuum to afford the titled product. Yield: 460 mg, 80%. ¹H NMR (400.13 MHz, CDCl₃) δ=2.71 (s, 18H), 6.10 (s, 5H), 6.23 (m, 2H), 6.61 (m, 2H). MS (EI): m/z 499 (M⁺).

### Example 9

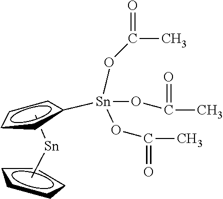

Synthesis of (η⁵—C₅H₅)Sn[(η⁵—C₅H₄)Sn(OCOCH₃)₃]. To the solution of Sc—SnCl₃ (467 mg, 1.17 mmol) in toluene (50 mL) at 0° C., 3 equiv. CH₃COONa (288 mg, 3.51 mmol) was added. The mixture was stirred at room temperature overnight, then followed by filtration through Celite. The filtrate was evaporated in vacuum to afford the product. Yield: 450 mg, 70%. MS (EI): m/z 544 (M⁺).

### Example 10

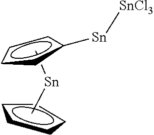

Synthesis of (η⁵—C₅H₅)Sn[(η⁵—C₅H₄)SSnCl₃] (Sc—SSnCl₃). At −78° C., the solution of Sc—SLi (2.87 g, 10 mmol) in DME (50 mL) was added dropwise to the solution of SnCl₄ (1.36 mL, 10 mmol) in hexane (100 mL) with vigorously stirring. After stirring for hours, all the volatiles were evaporated in vacuum. The reside was characterized by EI-MS and used directly for the following synthesis without further purification. Yield: 80%. MS (EI): m/z 505 (M⁺).

### Example 11

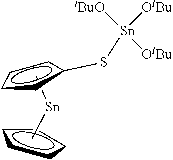

Synthesis of (η⁵—C₅H₅)Sn[(η⁵-C₅H₄)SSn(O^{t}Bu)₃]. To a solution of Sc—SSnCl₃ (513 mg, 1.02 mmol) in THF (50 mL) at −20° C., ^{t}BuOK (343 mg, 3.06 mmol) was added and the mixture was stirred at room temperature overnight, followed by the removal of the solvent. The residue was extracted by toluene and filtered through Celite; the filtrate was evaporated in vacuum to afford the titled product. Yield: 486 mg, 77%. MS (EI): m/z 618 (M⁺).

### Example 12

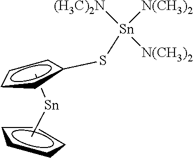

Synthesis of (η⁵—C₅H₅)Sn[(η⁵—C₅H₄)SSn(N(CH₃)₂)₃]. To a solution of Sc—SSnCl₃ (533 mg, 1.06 mmol) in toluene (50 mL) at −20° C., LiN(CH₃)₂ (162 mg, 3.18 mmol) was added. The mixture was stirred at room temperature overnight, then followed by filtration through Celite. The filtrate was evaporated in vacuum to afford the titled product. Yield: 396 mg, 70%. MS (EI): m/z 531 (M⁺).

### Example 13

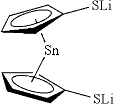

Synthesis of [(η⁵—C₅H₄SLi]2Sn(Sc—(SLi)₂). [(η⁵—C₅H₄Li]2Sn(ScLi₂) was prepared by the reaction of stannocene with 2 equiv. n-BuLi in THF at −78° C. At 0° C., to the solution of [(η⁵—C₅H₄Li]2Sn (from 1.22 g, 4.9 mmol stannocene, and 6.12 mL/1.6 M, 9.8 mmol n-BuLi) in Et₂O (50 mL), S₈ powder (316 mg, 9.88 mmol) was added. After stirring at room temperature overnight, the solvent was removed in vacuum to give the titled product. The product was used directly for the further reactions without further purification. Yield: 1.26 g, 80%.

### Example 14

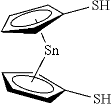

Synthesis of [(η⁵—C₅H₄SH]2Sn. At 0° C., the solution of Sc—(SLi)₂ (from 336 mg, 1.03 mmol) in DME (30 mL) was acidified by HCl (2 mL, 15%), then dried over MgSO₄, and filtered. The filtrate was evaporated in vacuum. The reside was extracted by hexane and filtered through Celite. The filtrate was evaporated in vacuum to give the titled product. Yield: 290 mg, 90%. ¹H NMR (400.13 MHz, CDCl₃) δ=6.32 (m, 4H), 6.69 (m, 4H). MS (EI): m/z 313 (M⁺).

### Example 15

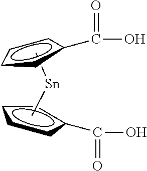

Synthesis of [(η⁵—C₅H₄COOH]2Sn. At −20° C., to the solution of ScLi₂ (from 670 mg, 2.69 mmol stannocene) in THF (100 mL), gaseous CO₂ was introduced to the solution with vigorously stirring. After stirring at room temperature for hours, the solvent was removed in vacuum, and the reside was dissolved in H₂O. Then the mixture was acidified by aqueous HCl solution (15%) to afford precipitate, which was collected and dried in high vacuum to give the titled product. Yield, 653 mg, 72%. ¹H NMR (400.13 MHz, CDCl₃) δ=5.78 (m, 4H), 5.93 (m, 4H). MS (EI): m/z 337 (M⁺).

### Example 16

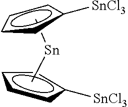

Synthesis of [(η⁵—C₅H₄SnCl₃)]2Sn (Sc—(SnCl₃)₂). Sc—(SnCl₃)₂ was prepared according to the similar manner of Sc—SnCl₃. At −78° C., the solution of ScLi₂ (from 2.63 g, 10.6 mmol stannocene) in THF (100 mL) was added dropwise to the solution of SnCl₄ (2.89 mL, 21.2 mmol) in hexane (100 mL) with vigorously stirring. The mixture was stirred for hour and then evaporated all the volatiles to give the titled product. Yield: 78%. MS (EI): m/z 697 (M⁺).

### Example 17

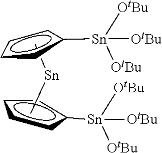

Synthesis of [(η⁵—C₅H₄)Sn(O^{t}Bu)₃)]₂Sn. At 0° C., to the solution of [(η⁵—C₅H₄)SnCl_{3]2}Sn (767 mg, 1.1 mmol) in THF (100 mL), KO^{t}Bu (739 mg, 6.6 mmol) was added with vigorously stirring. The mixture was then stirred at room temperature overnight. The solvent was removed in vacuum, and the reside was extracted by toluene. After filtered through Celite, the filtrate was evaporated in vacuum to result in the titled product. Yield: 609 mg, 60%. ¹H NMR (400.13 MHz, CDCl₃) δ=1.37 (s, 54H), 6.30 (m, 4H), 6.61 (m, 4H). MS (EI): m/z 922 (M⁺).

### Example 18

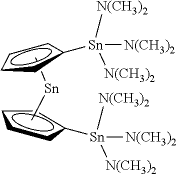

Synthesis of [(η⁵—C₅H₄)Sn(N(CH₃)₂)_{3]2}Sn. At −20° C., to the solution of [(η⁵—C₅H₄)SnCl_{3]2}Sn (782 mg, 1.12 mmol) in THF (100 mL), LiNMe₂ (345 mg, 6.77 mmol) was added with vigorously stirring. The mixture was slowly warmed to room temperature and stirred overnight. After removal of the solvent, the residue was extracted by toluene and filtered through Celite. The filtrate was evaporated in vacuum to result in the titled product. Yield: 670 mg, 79%. ¹H NMR (400.13 MHz, CDCl₃) δ=2.69 (s, 54H), 6.2 (m, 4H), 6.5 (m, 4H). MS (EI): m/z 748 (M⁺).

### Example 19

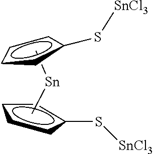

Synthesis of [(η⁵—C₅H₄)SSnCl₃)]₂Sn (Sc—(SSnCl₃)₂). A solution of Sc—(SLi)₂ (872 mg, 2.69 mmol) in DME (30 mL) was added dropwise to the solution of SnCl₄ (0.8 mL, 5.87 mmol) in hexane (100 mL) at −78° C. in hour with vigorously stirring. After stirring for hours, all the volatiles were removed. The reside was extracted by toluene and filtered through Celite. The filtrate was evaporated in vacuum to give the titled product. MS (EI): m/z 761 (M⁺).

### Example 20

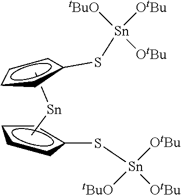

Synthesis of [(η⁵⁻C₅H₄)S—Sn(O^{t}Bu)₃)]₂Sn. KO^{t}Bu (296 mg, 2.64 mmol) was added to the solution of Sc—(SSnCl₃)₂ (1.01 g, 1.32 mmol) in THF (100 mL) at 0° C. The mixture was then stirred at room temperature overnight. After removal of the solvent, the residue was extracted by toluene and filtered through Celite. The filtrate was evaporated in vacuum to give the titled product. Yield: 810 mg, 62%. MS (EI): m/z 986 (M⁺).

### Example 21

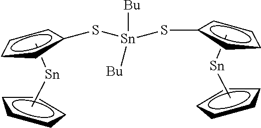

Synthesis of [(η⁵—C₅H₅)Sn(η⁵—C₅H₄S]₂SnBu₂. To the solution of Sc—SLi (677 mg, 2.36 mmol) in DME (30 ml) at 0° C., Bu₂SnCl₂ (356 mg, 1.18 mmol) was added with vigorously stirring. After stirred at room temperature overnight, the mixture was filtered through Celite. The filtrate was evaporated in vacuum to result in the titled product. Yield: 710 mg, 76%. ¹H NMR (400.13 MHz, CDCl₃) δ=1.23 (s, 18), 6.10 (s, 10H), 6.26 (m, 4H), 6.60 (m, 4H). MS (EI): m/z 793 (M⁺).

It is understood that the above described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the sprit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organotin compound, having a chemical structure bearing stannocenyl selected from the following: 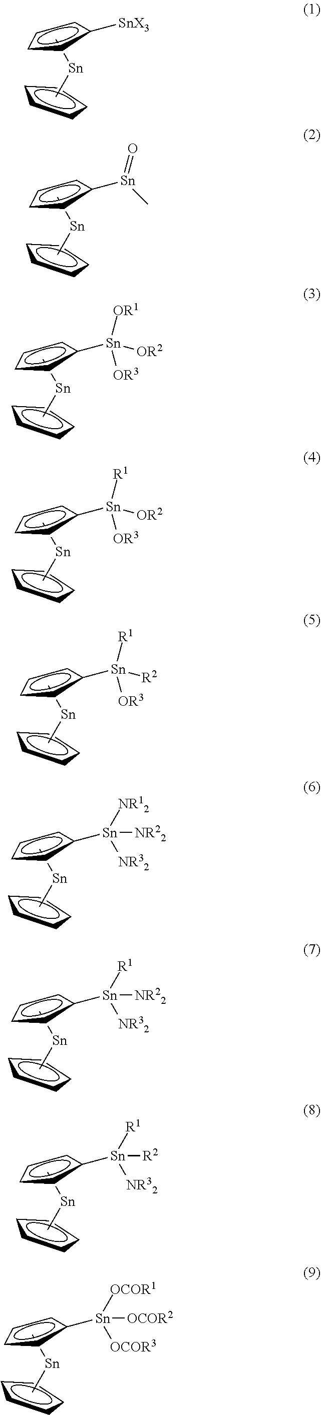 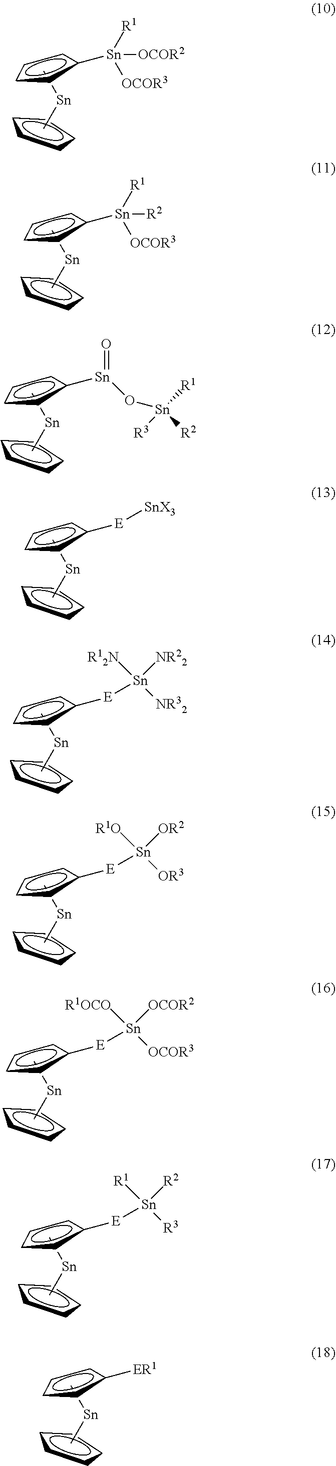 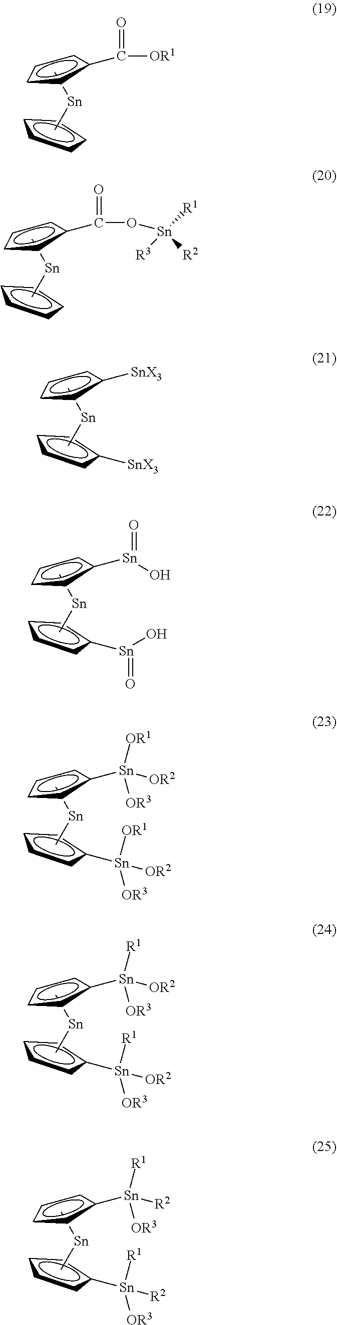 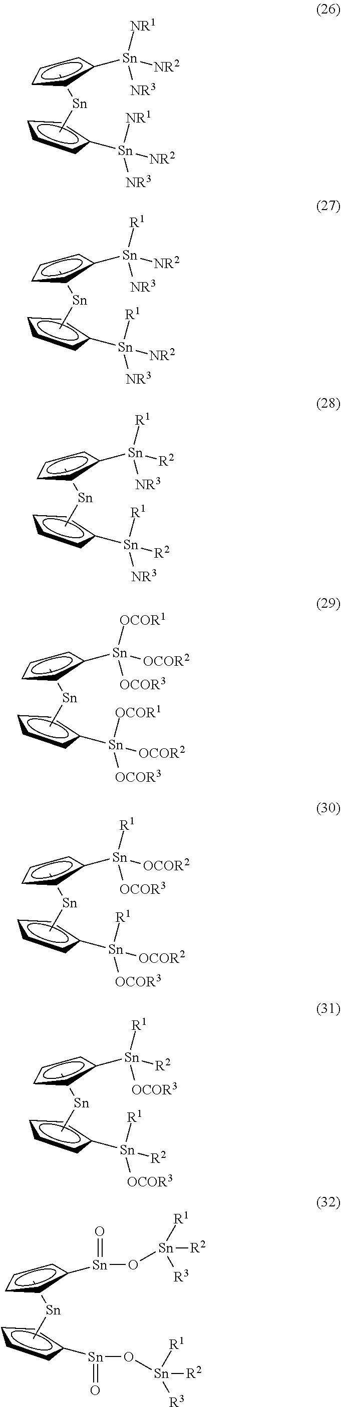 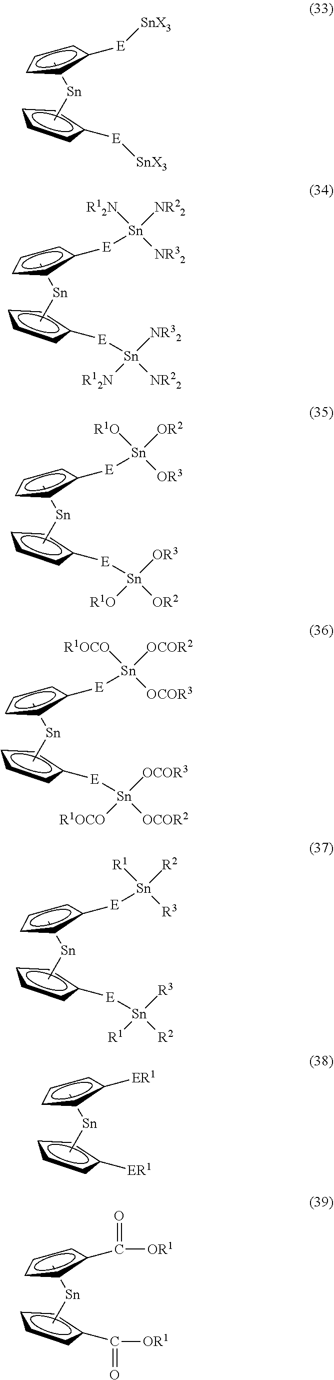 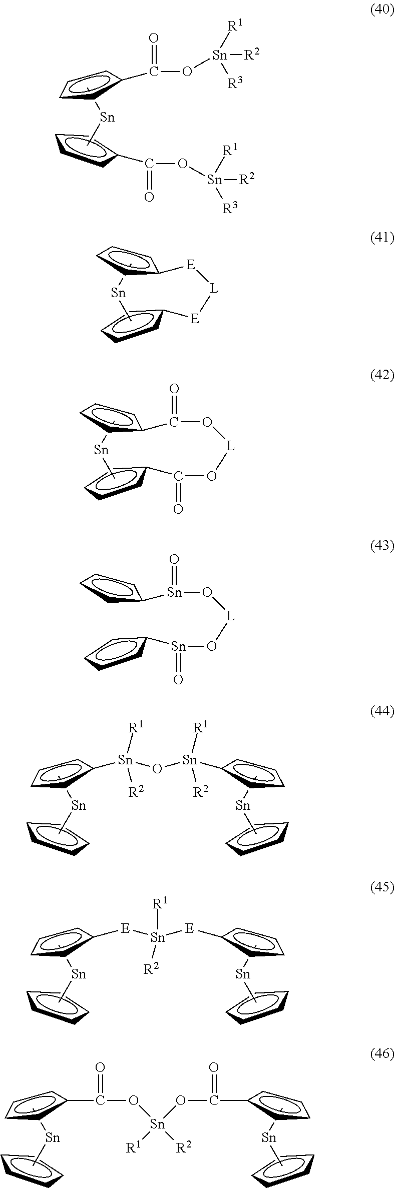
wherein R¹, R², R³, are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms;
E=O, S, Se, or Te; X=F, Cl, Br, or I;
L is an alkyl, alkenyl, alkylene, alkynyl, or cycloalkyl group with 1 to 20 carbon atoms, or an aryl group with 6-20 carbon atoms, or an amino, cyano, ether, ester, halide, nitro, silyl, thiol, or carbonyl group.

2. The organotin compound of claim 1, wherein stannocenyl is bis(cyclopentadienyl)tin, or substituted bis(cyclopentadienyl)tin, wherein cyclopentadienyl comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴ or η⁵ of isomers, wherein R is H, an alkyl, alkenyl, alkynyl, or cycloalkyl group with 1 to 20 carbon atoms, or an aryl group with 6-20 carbon atoms, or an amino, cyano, ether, ester, halide, nitro, silyl, thiol, or carbonyl group.

3. The organotin compound of claim 2, wherein R is H, methyl, ethyl, propyl, butyl, or phenyl.

4. The organotin compound of claim 1, wherein R¹, R², R³ are each independently alkyl, cycloalkenyl, or aryl; E=O, S, Se, or Te; X=Cl.

5. The organotin compound of claim 1, wherein R¹, R², R³ are each independently methyl, ethyl, propyl, n-butyl, t-butyl, or cyclopentadienyl.

6. A method of developing photolithography pattern, comprising:
forming an organotin photoresist solution composition;
wherein the forming the organotin photoresist solution composition comprises:
(stannocenyl)tin compound, a solvent, and/or an additive;
depositing organotin photoresist solution composition over a substrate to form a photoresist layer;
exposing organotin photoresists layer to actinic radiation to form a latent pattern; and
developing the latent pattern by applying sublimation or vaporization method to remove unexposed organotin photoresist to form a photolithography pattern.

7. The method of claim 6, wherein stannocenyl is bis(cyclopentadienyl)tin, or substituted bis(cyclopentadienyl)tin, wherein cyclopentadienyl comprises cyclopentadienyl C₅H₅ group, or substituted cyclopentadienyl C₅H₃R, C₅H₂R₂, C₅HR₃, C₅R₄, or C₅R₅ group, wherein R is H, an alkyl, alkenyl, alkynyl, or cycloalkyl group with 1 to 20 carbon atoms, or an aryl group with 6-20 carbon atoms, or an amino, cyano, ether, ester, halide, nitro, silyl, thiol, or carbonyl group.

8. The method of claim 6, wherein (stannocenyl)tin compound is one or more selected from the following: 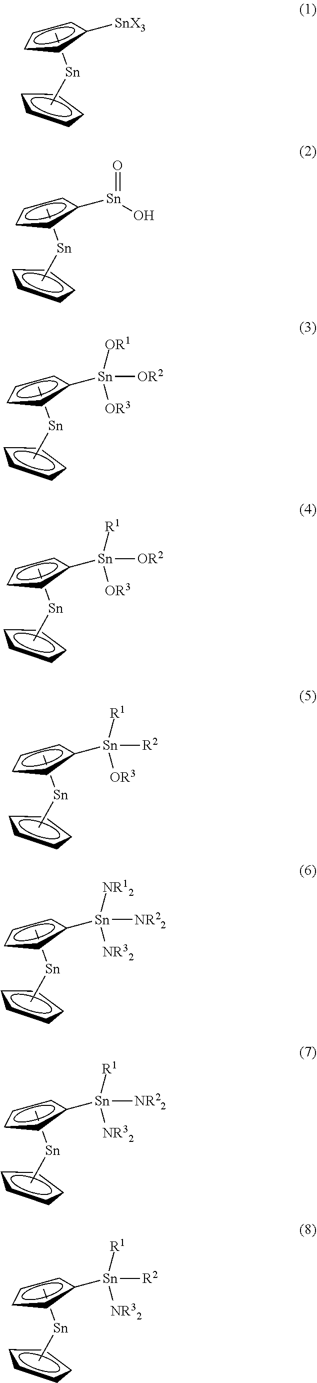 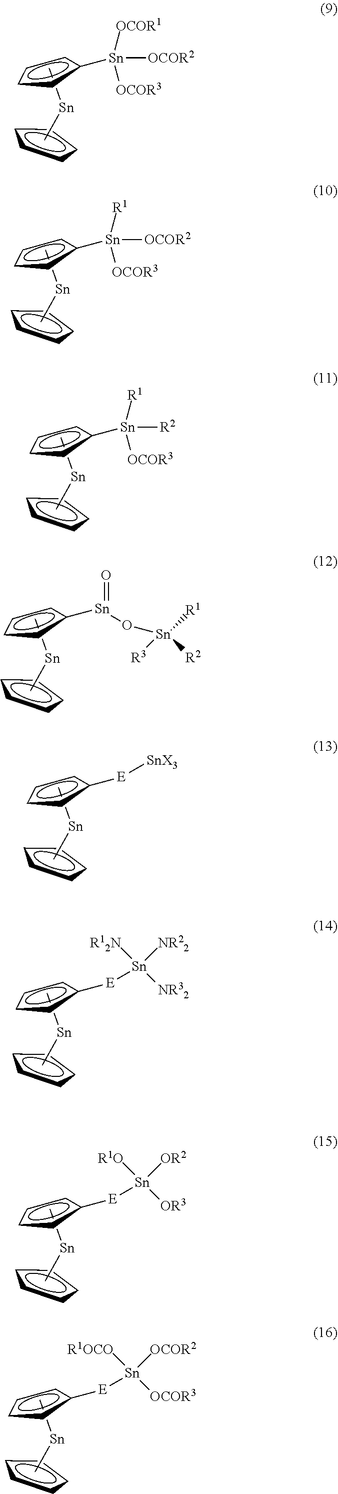 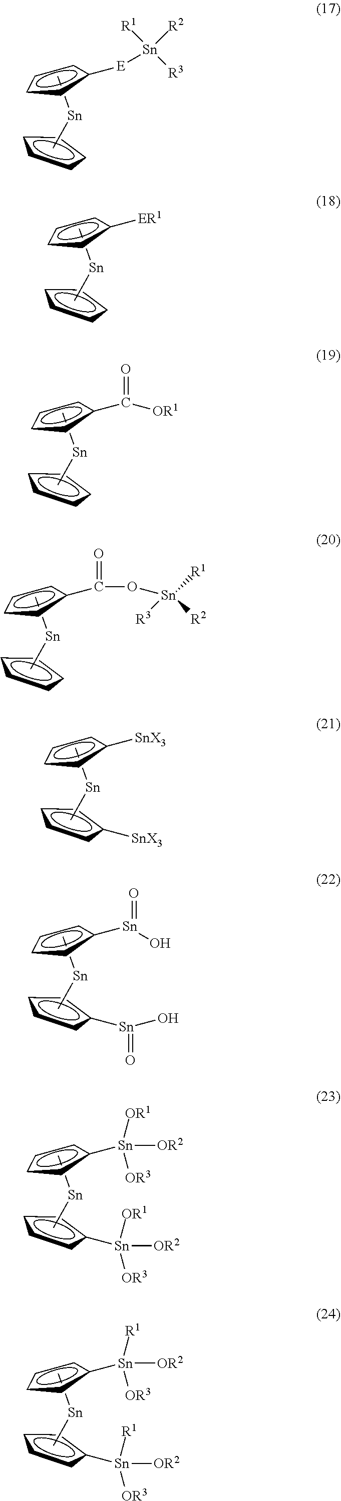 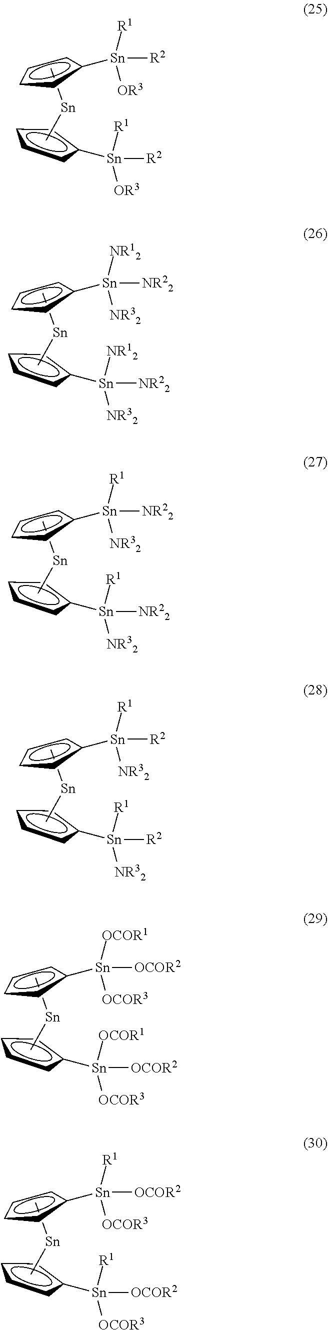 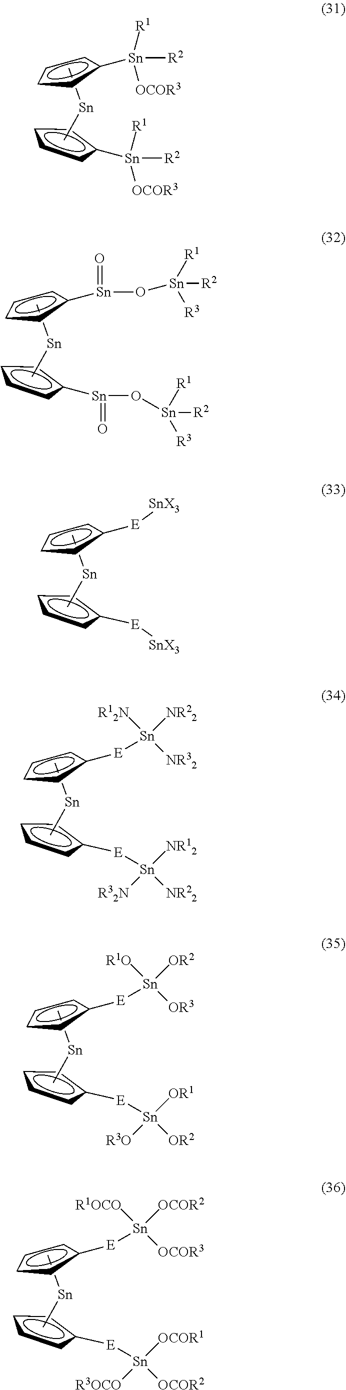 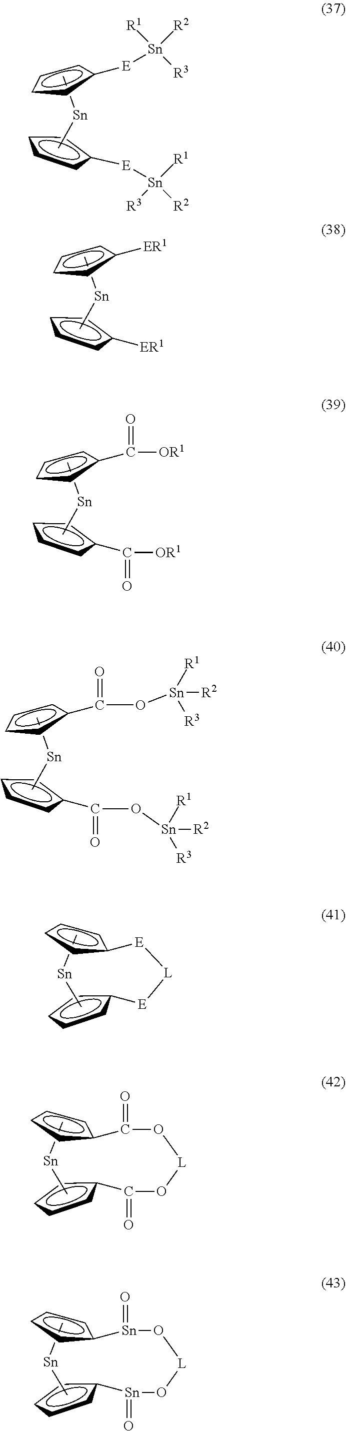 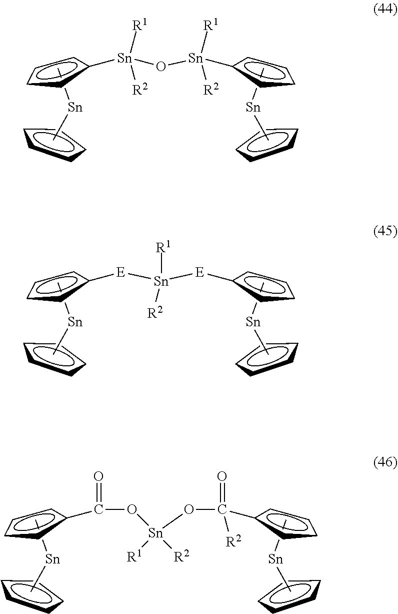
wherein R¹, R², R³ are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms;
E=O, S, Se, or Te; X=F, Cl, Br, or I;
L is an alkyl, alkenyl, alkylene, alkynyl, or cycloalkyl group with 1 to 20 carbon atoms, or an aryl group with 6-20 carbon atoms, or an amino, cyano, ether, ester, halide, nitro, silyl, thiol, or carbonyl group.

9. The method of claim 8, wherein cycloalkenyl group comprises a substituted and unsubstituted C₄ to C₈ aliphatic unsaturated organic groups including at least one double bond.

10. The method of claim 8, wherein (stannocenyl)tin compound comprises substituted cyclopentadienyl C₅H₄ group, and/or cyclopentadienyl group C₅H₅; R¹, R², R³ are independently methyl, ethyl, propyl, n-butyl, t-butyl, or cyclopentadienyl; E=O, S, Se, or Te; and X=Cl.

11. The method of claim 6, wherein the exposing organotin photoresists layer to actinic radiation may be under molecular oxygen, air, ozone, water, or hydrogen peroxide atmosphere for the formation of photolithographic latent pattern.

12. The method of claim 6, wherein the actinic radiation is extreme ultraviolet radiation, deep ultraviolet radiation, e-beam radiation, X-ray radiation, or ion-beam radiation.

13. The method of claim 6, wherein the sublimation or vaporization is carried out under vacuum ranging from 0.0001 torr to 100 torr and a temperature ranging from 20° C. to 300° C.

14. The method of claim 6, wherein the additive comprises organic thiol, organic alcohol, organic amine, organic amide, organic carboxylic acid, organic phosphine, organic phosphine oxide, organic phosphonic acid, or a combination thereof.

15. An organotin photoresist composition, comprising:
(stannocenyl)tin compound, a solvent, and/or an additive;
wherein (stannocenyl)tin compound is one or more selected from the following: 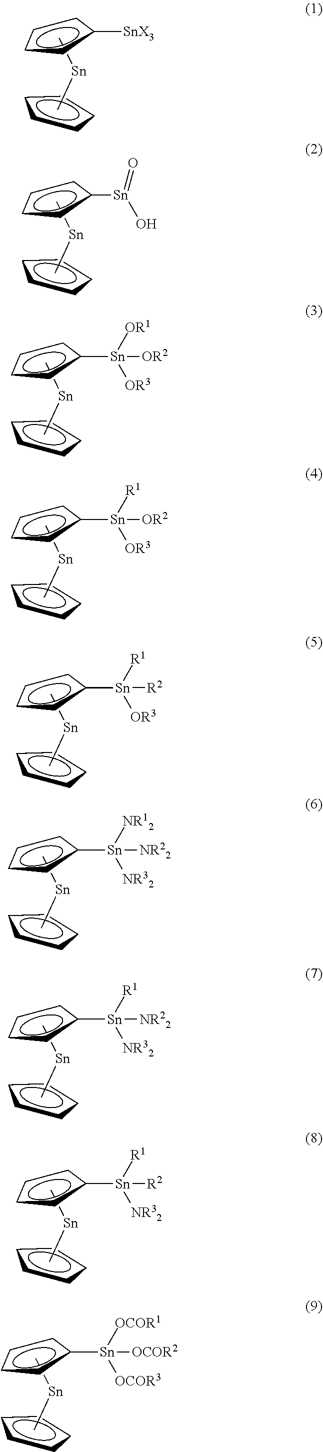 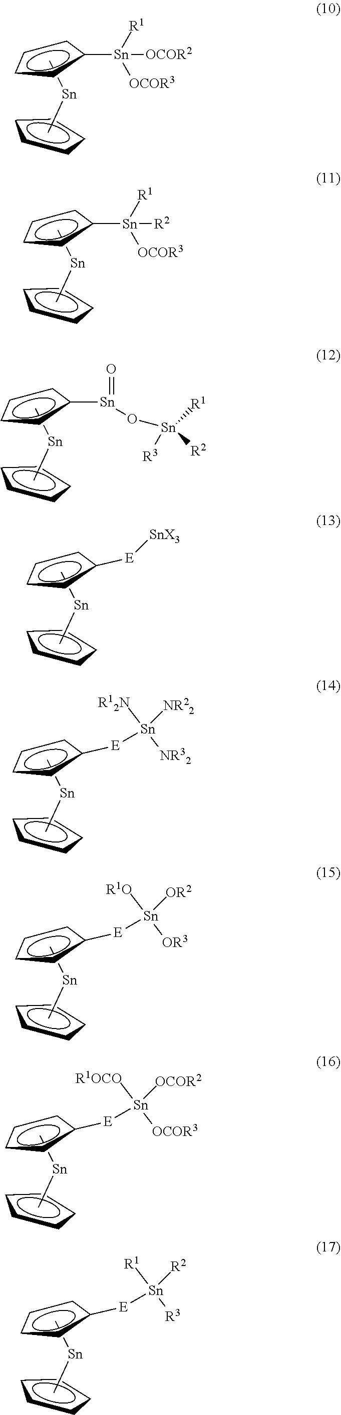 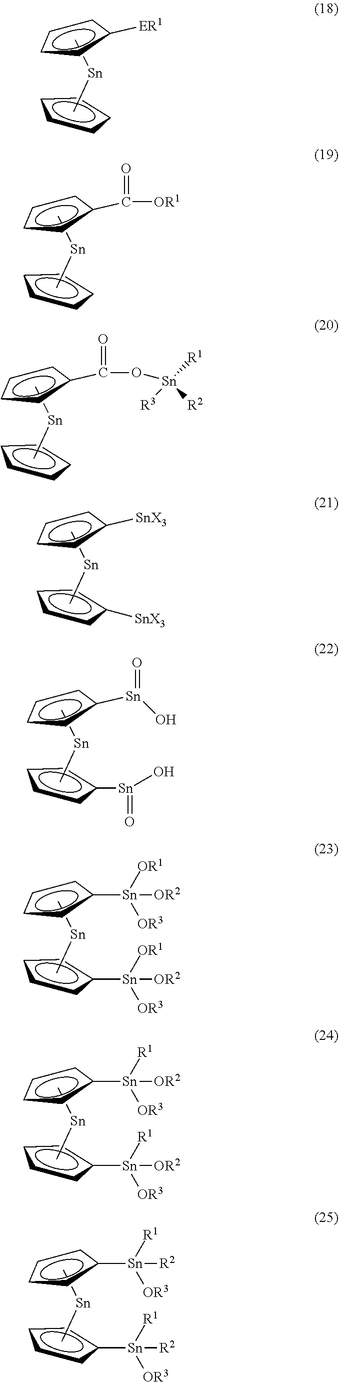 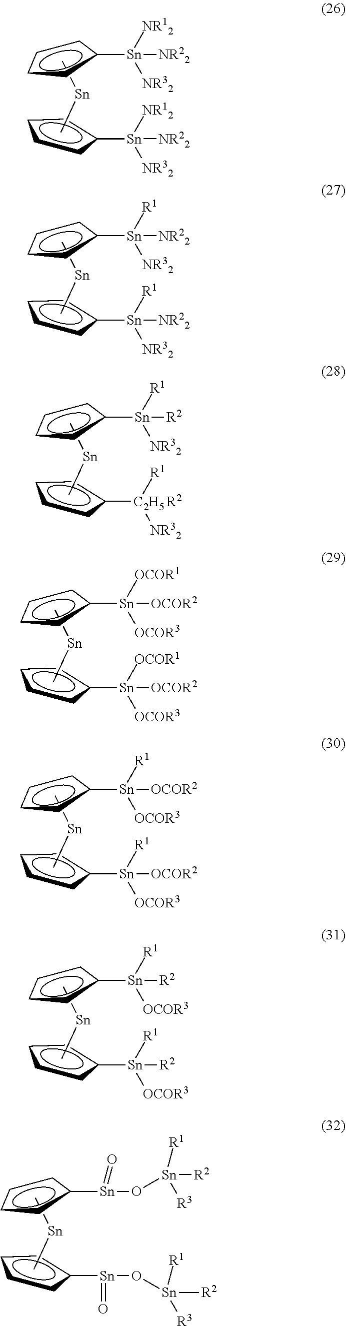 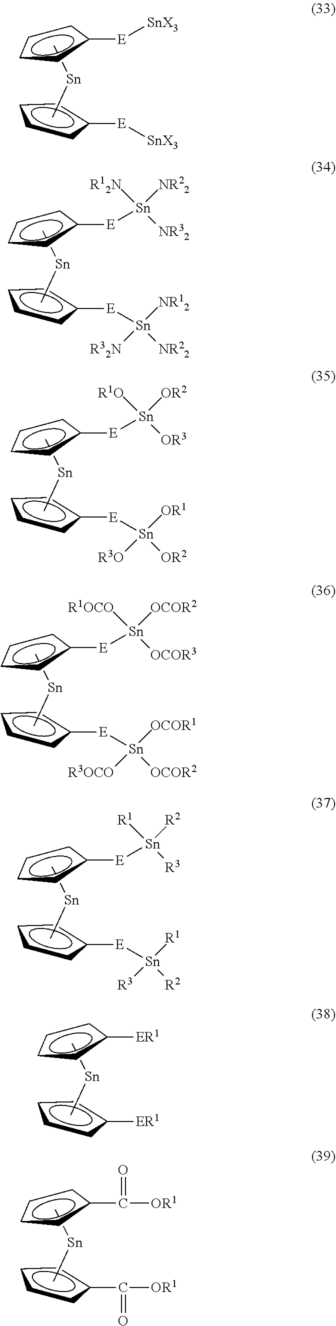 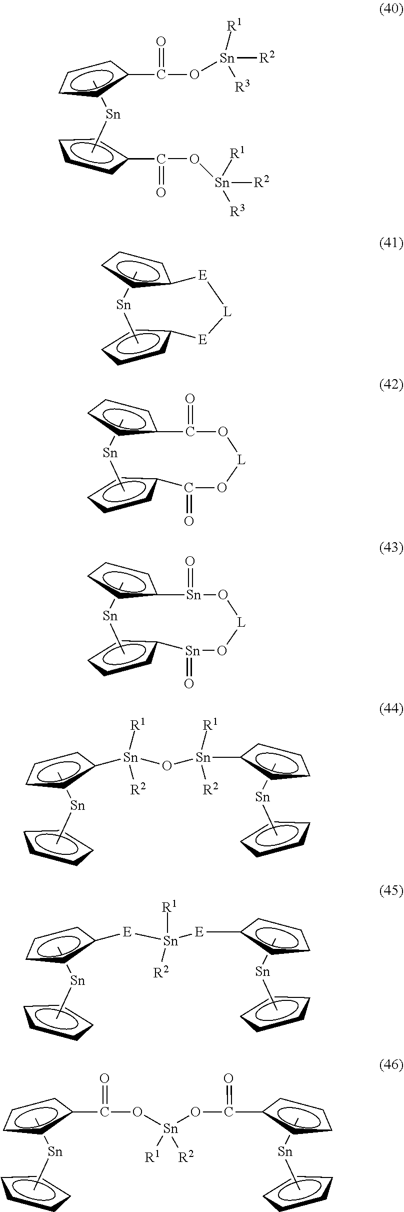
wherein R¹, R², R³, are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms;
E=O, S, Se, or Te; X=F, Cl, Br, or I;
L is an alkyl, alkenyl, alkylene, alkynyl, or cycloalkyl group with 1 to 20 carbon atoms, or an aryl group with 6-20 carbon atoms, or an amino, cyano, ether, ester, halide, nitro, silyl, thiol, or carbonyl group.

16. The organotin photoresist composition of claim 15, wherein stannocenyl is bis(cyclopentadienyl)tin, or substituted bis(cyclopentadienyl)tin, wherein cyclopentadienyl comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴, or η⁵ of isomers, wherein R is H, an alkyl, alkenyl, alkynyl, or cycloalkyl group with 1 to 20 carbon atoms, or an aryl group with 6-20 carbon atoms, or an amino, cyano, ether, ester, halide, nitro, silyl, thiol, or carbonyl group.

17. The organotin photoresist composition of claim 16, wherein R is H, methyl, ethyl, propyl, butyl, or phenyl.

18. The organotin photoresist composition of claim 15, R¹, R², R³ are independently methyl, ethyl, propyl, n-butyl, t-butyl, or cyclopentadienyl; E=O, S, Se or Te; X=Cl; L is methylene, ethylene, or propylene.

19. The organotin photoresist composition of claim 15, wherein the solvent comprises 4-methyl-2-pentenol, ethanol, methanol, propanol, butanol, benzene, toluene, xylene, or a combination thereof.

20. The organotin photoresist composition of claim 15, wherein the (stannocenyl)tin compound may be used as precursor for preparing organotin photoresist.
